(19) United States
(12) Patent Application Publication
(10) Pub. No.: US 2025/0351657 A1
(43) Pub. Date: Nov. 13, 2025

(54) DISPLAY DEVICE, ELECTRONIC DEVICE INCLUDING THE SAME, AND METHOD FOR MANUFACTURING THE DISPLAY DEVICE

(71) Applicant: Samsung Display Co., Ltd., Yongin-si (KR)

(72) Inventors: HIDEKAZU HAYASHI, Yongin-si (KR); JAHUN KOO, Yongin-si (KR); BYUNG-GON KUM, Yongin-si (KR); DA WUN KIM, Yongin-si (KR); JI SANG SEO, Yongin-si (KR); TAEK-SUN SHIN, Yongin-si (KR)

(21) Appl. No.: 19/187,562

(22) Filed: Apr. 23, 2025

(30) Foreign Application Priority Data
May 7, 2024 (KR) 10-2024-0060046

(51) Int. Cl. H10H 29/85; H10H 29/01

(52) U.S. Cl. CPC H10H 29/8581; H10H 29/0365; H10H 29/8582

(57) ABSTRACT

A display device, an electronic device including the display device, and a method for manufacturing the display device are disclosed. The display device may include a display panel, a heat dissipating member below the display panel, and a bottom chassis below the heat dissipating member. The heat dissipating member may include a heat dissipating plate including graphite, an adhesive layer on at least one surface of the heat dissipating plate, wherein the adhesive layer may include a polyurethane, and a base material film spaced and/or apart (e.g., spaced apart or separated) from the heat dissipating plate with the adhesive layer therebetween. The adhesive layer may include a polyol that includes a polycarbonate polyol. The adhesive layer may include a first portion adjacent to the heat dissipating plate and a second portion adjacent to the base material film.

### CROSS-REFERENCE TO RELATED APPLICATION

The present application claims priority to and the benefit of Korean Patent Application No. 10-2024-0060046, filed on May 7, 2024, in the Korean Intellectual Property Office, the entire disclosure of which is incorporated herein by reference.

### BACKGROUND

### 1. Field

One or more embodiments of the present disclosure relate to a display device, an electronic device including the display device, and a method for manufacturing the display device, and, for example, to a display device and an electronic device with improved or enhanced reliability and display characteristics and a method for manufacturing the display device.

### 2. Description Of The Related Art

Multimedia electronic apparatuses, such as televisions, mobile phones, tablet computers, navigation units, and game consoles, may include display devices to display images. The display devices may generate images and include display panels to provide the generated images for users. The display panels may each include a plurality of pixels which generate an image and a driving part which drives the pixels.

The multimedia electronic apparatuses may include display devices to display images and electronic parts which perform one or more functions. Based on improvements or enhancements in high performance and a reduction in thickness of the electronic apparatuses together with technology development, the display devices and the electronic parts, embedded in the electronic apparatuses, may be improved or enhanced in large capacity and high density integration. The display devices and the electronic parts generate much heat inside the electronic apparatuses, and the heat generated in the electronic apparatuses cause a reduction in lifespan of products or trouble and malfunctioning of the electronic parts and the display devices.

### SUMMARY

One or more aspects of embodiments of the present disclosure are directed toward a display device and an electronic device having an improved or enhanced heat dissipation function and also capable of preventing a white blur and/or the like from occurring (or reducing a degree or occurrence of a white blur and/or the like) on an adhesive layer provided in the display device to prevent occurrence of a visible defect (or to reduce a degree or occurrence of a visible defect) and a method for manufacturing the display device.

Additional aspects of embodiments will be set forth in part in the description which follows and, in part, will be apparent from the description or may be learned by practice of the presented embodiments of the disclosure.

One or more embodiments of the present disclosure provide a display device including a display panel, a heat dissipating member below the display panel, and a bottom chassis below the heat dissipating member. The heat dissipating member includes a heat dissipating plate including graphite, an adhesive layer on at least one surface of the heat dissipating plate, wherein the adhesive layer includes a polyurethane, and a base material film spaced and/or apart (e.g., spaced apart or separated) from the heat dissipating plate with the adhesive layer therebetween. The adhesive layer includes a polyol, and the polyol includes a polycarbonate polyol. The adhesive layer includes a first portion adjacent to the heat dissipating plate and a second portion adjacent to the base material film, and in the adhesive layer, a content (e.g., amount) of the polycarbonate polyol of the first portion is less than a content (e.g., amount) of the polycarbonate polyol of the second portion.

In one or more embodiments, in the adhesive layer, the content (e.g., amount) of the polycarbonate polyol may gradually increase from the heat dissipating plate to the base material film.

In one or more embodiments, the adhesive layer may include a first sub-adhesive layer on one surface of the at least one surface of the heat dissipating plate and a second sub-adhesive layer between the first sub-adhesive layer and the base material film. The content (e.g., amount) of the polycarbonate polyol of the first sub-adhesive layer may be less than the content (e.g., amount) of the polycarbonate polyol of the second sub-adhesive layer.

In one or more embodiments, a thickness of the second sub-adhesive layer may be greater than a thickness of the first sub-adhesive layer.

In one or more embodiments, the adhesive layer may include a polyol including the polycarbonate polyol and a polyisocyanate that crosslinks with the polyol. If (e.g., when) a total content (e.g., amount) of the polyol and the polyisocyanate is taken to be 100 parts by weight, the content (e.g., amount) of the polycarbonate polyol may be about 20 parts by weight to about 40 parts by weight.

In one or more embodiments, in the first portion, if (e.g., when) the total content (e.g., amount) of the polyol and the polyisocyanate is taken to be 100 parts by weight, the content (e.g., amount) of the polycarbonate polyol may be about 20 parts by weight to about 25 parts by weight. In the second portion, if (e.g., when) the total content (e.g., amount) of the polyol and the polyisocyanate is taken to be 100 parts by weight, the content (e.g., amount) of the polycarbonate polyol may be about 35 parts by weight to about 40 parts by weight.

In one or more embodiments, a first surface of the adhesive layer may be in contact with one surface of the at least one surface of the heat dissipating plate. A second surface of the adhesive layer, which opposes the first surface, may be in contact with one surface of the base material film.

In one or more embodiments, the heat dissipating member may further include an anti-static layer spaced and/or apart (e.g., spaced apart or separated) from the adhesive layer with the base material film therebetween.

In one or more embodiments, the heat dissipating plate may include a bottom surface adjacent to the bottom chassis and a top surface adjacent to the display panel. The adhesive layer may include a first adhesive layer on the bottom surface and a second adhesive layer on the top surface.

In one or more embodiments, at least one hole that passes through the first adhesive layer in a thickness direction may be provided in the first adhesive layer.

In one or more embodiments, the display device may further include a foam tape between the base material film and the bottom chassis.

In one or more embodiments, the heat dissipating plate may have a thickness of about 700 micrometers to about 1000 micrometers. Each of the adhesive layer and the base material film may have a thickness of about 10 micrometers to about 100 micrometers.

In one or more embodiments, the display panel may include a first non-folding area, a second non-folding area, and a folding area between the first non-folding area and the second non-folding area.

In one or more embodiments, the adhesive layer may further include a perfluoropolyether (PFPE). The perfluoropolyether may be covalently bonded to the polycarbonate polyol.

In one or more embodiments, the display device may further include an additional adhesive layer between the heat dissipating member and the display panel. In one or more embodiments of the present disclosure, an electronic device

includes a display panel and a heat dissipating member below the display panel. The heat dissipating member includes a heat dissipating plate including graphite, an adhesive layer on at least one of a bottom surface or a top surface of the heat dissipating plate, and a base material film spaced and/or apart (e.g., spaced apart or separated) from the heat dissipating plate with the adhesive layer therebetween. The adhesive layer includes a polyol including a polycarbonate polyol and a polyisocyanate that crosslinks with the polyol, and if (e.g., when) a total content (e.g., amount) of the polyol and the polyisocyanate is taken to be 100 parts by weight, a content (e.g., amount) of the polycarbonate polyol is about 20 parts by weight to about 40 parts by weight. The adhesive layer includes a first portion adjacent to the heat dissipating plate and a second portion adjacent to the base material film, and in the adhesive layer, a content (e.g., amount) of the polycarbonate polyol of the first portion is less than a content (e.g., amount) of the polycarbonate polyol of the second portion.

The electronic device may be a smartphone, a television, a monitor, a tablet, an electric vehicle, a mobile phone, a tablet personal computer (PC), a mobile communication terminal, an electronic notebook, an electronic book, a portable multimedia player (P MP), a navigation device, an ultra-mobile PC (UMPC), a laptop computer, a billboard, an Internet of Things (IoT) device, a smartwatch, a watch phone, and/or a head-mounted display (HMD).

In one or more embodiments, the adhesive layer may include a first adhesive layer on the bottom surface and a second adhesive layer on the top surface. The first adhesive layer may include a first portion adjacent to the heat dissipating plate and a second portion adjacent to the base material film, and in the first adhesive layer, the content (e.g., amount) of the polycarbonate polyol of the first portion may be less than the content (e.g., amount) of the polycarbonate polyol of the second portion.

In one or more embodiments of the present disclosure, a method for manufacturing a display device includes providing a display panel and forming or providing a heat dissipating member below the display panel. The forming or providing of the heat dissipating member includes providing a heat dissipating plate including graphite, providing a base material film, providing an adhesive composition between the heat dissipating plate and the base material film to form or provide a preliminary adhesive layer, and curing the preliminary adhesive layer to attach the heat dissipating plate and the base material film to each other. The preliminary adhesive layer includes a polyol that includes a polycarbonate polyol, and the preliminary adhesive layer includes a first preliminary portion adjacent to the heat dissipating plate and a second preliminary portion adjacent to the base material film. In the preliminary adhesive layer, a content (e.g., amount) of the polycarbonate polyol of the first preliminary portion is less than a content (e.g., amount) of the polycarbonate polyol of the second preliminary portion.

In one or more embodiments, the preliminary adhesive layer may include a polyol including the polycarbonate polyol and a polyisocyanate that crosslinks with the polyol. If (e.g., when) a total content (e.g., amount) of the polyol and the polyisocyanate is taken to be 100 parts by weight, a content (e.g., amount) of the polycarbonate polyol may be about 20 parts by weight to about 40 parts by weight.

In one or more embodiments, the adhesive composition may further include a perfluoropolyether. The method may further include providing a functional film including a fluorine on one side of the adhesive composition before the forming or providing of the preliminary adhesive layer.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIGS. 1A-1C each is a perspective view of an electronic apparatus (or an electronic device) according to one or more embodiments of the present disclosure;

FIG. 2A is an exploded perspective view of an electronic apparatus (or an electronic device) according to one or more embodiments of the present disclosure;

FIG. 2B is a block diagram of an electronic apparatus (or an electronic device) according to one or more embodiments of the present disclosure;

FIG. 3 is a plan view of a display panel according to one or more embodiments of the present disclosure;

FIG. 4 is a cross-sectional view of a display device according to one or more embodiments of the present disclosure;

FIG. 5 is a cross-sectional view of a portion of a display module according to one or more embodiments of the present disclosure;

FIG. 6 is an exploded perspective view of one or more components of a display device according to one or more embodiments of the present disclosure;

FIG. 7 is a cross-sectional view of one or more components of a display device according to one or more embodiments of the present disclosure;

FIGS. 8 and 9 each is an enlarged cross-sectional view of one or more components of a heat dissipating member according to one or more embodiments of the present disclosure;

FIG. 10 is an enlarged cross-sectional view of one or more components of a heat dissipating member according to one or more embodiments of the present disclosure;

FIG. 11A is a flowchart of a method for manufacturing a display device according to one or more embodiments of the present disclosure;

FIG. 11B is a flowchart of one or more acts of a method for manufacturing a display device according to one or more embodiments of the present disclosure; and

FIGS. 12A-12C each is a cross-sectional view of one or more acts of a method for manufacturing a display device according to one or more embodiments of the present disclosure.

### DETAILED DESCRIPTION

The subject matter of the present disclosure may be modified in one or more forms, and example embodiments thereof will be illustrated in the drawings and described herein in more detail. The subject matter of the present disclosure should not be construed as being limited to one or more embodiments set forth herein. Rather, these embodiments are provided as examples so that this disclosure will be thorough and complete and will fully convey the aspects and features of the present disclosure to those skilled in the art.

The same reference numerals are used for substantially the same

components or elements in the drawings, and redundant descriptions of substantially the same components or elements may not be provided.

It will be understood that if (e.g., when) an element (or a region, a layer, a section, and/or the like) is referred to as being “on”, “connected to”, or “coupled to” another element, it may be directly on, directly connected, or directly coupled to the other element or a third element may be between the elements. In contrast, if (e.g., when) an element is referred to as being “directly on” another element, there may be no intervening elements present.

Like reference numbers or symbols refer to like elements throughout. In addition, in the drawings, the thickness, the ratio, and the dimension of elements may be exaggerated for effective description of the technical contents. The term “and/or” includes one or more combinations which may be defined by relevant elements.

It will be understood that, although the terms “first,” “second,” and/or the like may be used herein to describe one or more elements, these elements should not be limited by these terms. These terms are only used to distinguish one element from another element. For example, a first element could be termed a second element without departing from the spirit and scope of the present disclosure, and similarly, a second element could be termed a first element. As used herein, the singular forms are intended to include the plural forms as well, unless the context clearly indicates otherwise.

In one or more embodiments, the terms, such as “below”, “beneath”, “on” and “above”, are used for illustrating the relation of elements depicted in the drawings. The terms are relative concept and are illustrated based on the direction depicted in the drawing.

It will be further understood that the terms, such as “includes/including” or “has/have/having”, if (e.g., when) used herein, specify the presence of stated features, numerals, steps, acts, operations, elements, parts, or the combination thereof, but do not preclude the presence or addition of one or more other features, numerals, steps, acts, operations, elements, parts, or the combination thereof. Also, the terms “comprise(s)/comprising,” “include(s)/including,” “have/has/having” or similar terms include or support the terms “consisting of” and “consisting essentially of,” indicating the presence of stated features, integers, steps, acts, operations, elements, and/or components, without or essentially without the presence of other features, integers, steps, acts, operations, elements, components, and/or groups thereof.

Unless otherwise defined, all terms (including technical and scientific terms) used herein have substantially the same meaning as commonly understood by one of ordinary skill in the art to which this disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

Hereinafter, a display device and an electronic apparatus (or an electronic device) including the display device according to one or more embodiments of the present disclosure will be described with reference to the accompanying drawings.

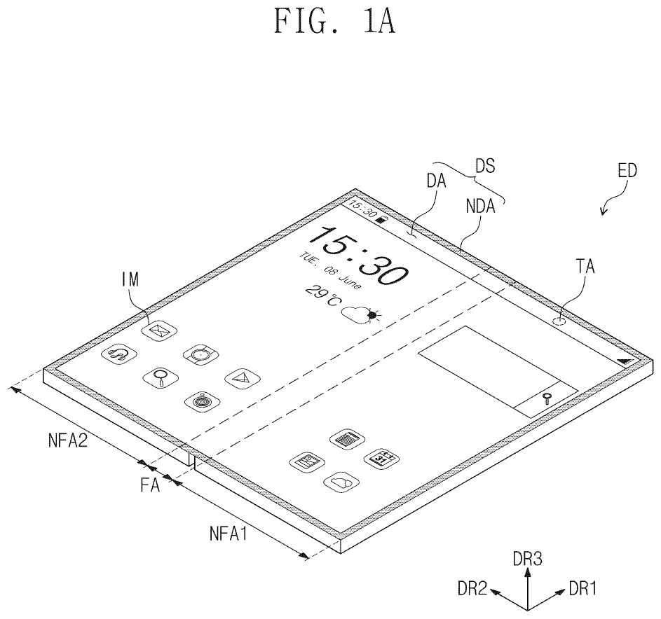

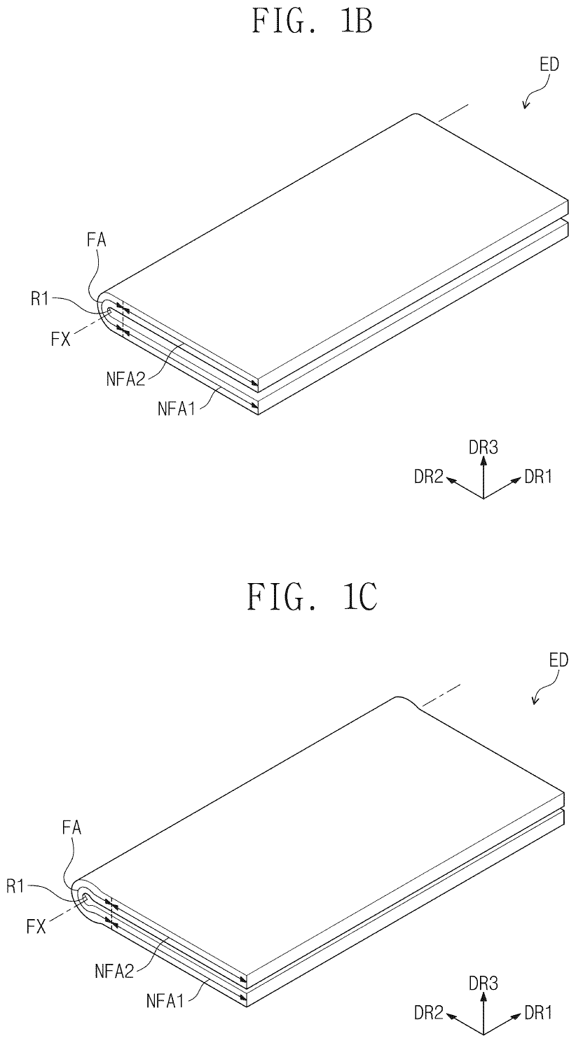

FIGS. 1A-1C each is a perspective view of an electronic apparatus (or an electronic device) according to one or more embodiments of the present disclosure. FIG. 1A illustrates a spread state, and FIGS. 1B and 1C each illustrates a folded state.

Referring to FIGS. 1A-1C, an electronic apparatus (or an electronic device) ED according to one or more embodiments of the present disclosure may include a display surface DS defined by a first direction DR1 and a second direction DR2 that crosses the first direction DR1. The electronic apparatus ED may provide an image IM for a user through the display surface DS.

The display surface DS may include a display area DA and a non-display area NDA around (or surrounding) the display area DA. The display area DA may display the image IM, and the non-display area NDA may not display the image IM. The non-display area NDA may be around (e.g., surround) the display area DA. However, embodiments of the present disclosure are not limited thereto, and a shape of the display area DA and a shape of the non-display area NDA may be changed.

The display surface DS may include a sensing area TA. The sensing area TA may be a partial area of the display area DA. The sensing area TA may have a higher transmittance than the other area of the display area DA. Hereinafter, the other area of the display area DA except for the sensing area TA may be defined as a general display area.

A light signal, for example, visible light and/or infrared light, may travel to the sensing area TA. The electronic apparatus ED may capture an external image using visible light that passes through the sensing area TA or may determine or select an approach of an external object using infrared light. As an example, one sensing area TA is illustrated in FIG. 1A. However, embodiments of the present disclosure are not limited thereto, and the sensing area TA may be provided in plurality.

Hereinafter, a direction that substantially perpendicularly crosses a plane defined by the first direction DR1 and the second direction DR2 is defined as a third direction DR3. The third direction DR3 may serve as a basis for distinguishing a front surface and a rear surface of each member. The term “on a plane” used herein may be defined as a state as viewed in the third direction DR3. Hereinafter, the first direction DR1, the second direction DR2, and the third direction DR3 may be directions indicated by the first directional axis, the second directional axis, and the third directional axis, respectively, and are designated by like reference numbers or symbols.

The electronic apparatus ED may include a folding area FA and a plurality of non-folding areas NFA1 and NFA2. The plurality of non-folding areas NFA1 and NFA2 may include a first non-folding area NFA1 and a second non-folding area NFA2. The folding area FA may be between the first non-folding area NFA1 and the second non-folding area NFA2 in the second direction DR2.

As illustrated in FIG. 1B, the folding area FA may be folded around (or surrounding) a folding axis FX substantially parallel to the first direction DR1. The folding area FA may have a set or predetermined curvature and radius of curvature R1.

The electronic apparatus ED may be inner-folded so that the first non-folding area NFA1 and the second non-folding area NFA2 face each other, and the display surface DS is not exposed to the outside.

In one or more embodiments of the present disclosure, the electronic apparatus ED may be outer-folded so that the display surface DS is exposed to the outside. In one or more embodiments of the present disclosure, the electronic apparatus ED may be provided to repeat an operation from a spreading operation to an inner-folding or outer-folding operation, or vice versa, but embodiments of the present disclosure are not limited thereto. In one or more embodiments of the present disclosure, the electronic apparatus ED may be provided so as to select any one selected from among the spreading operation, the inner-folding operation, and the outer-folding operation.

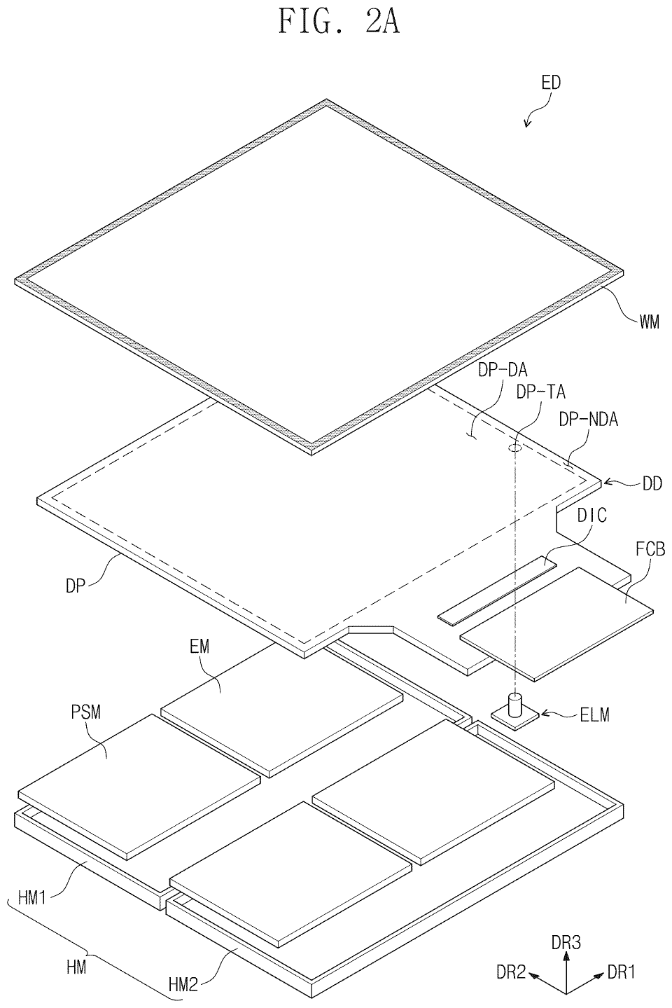

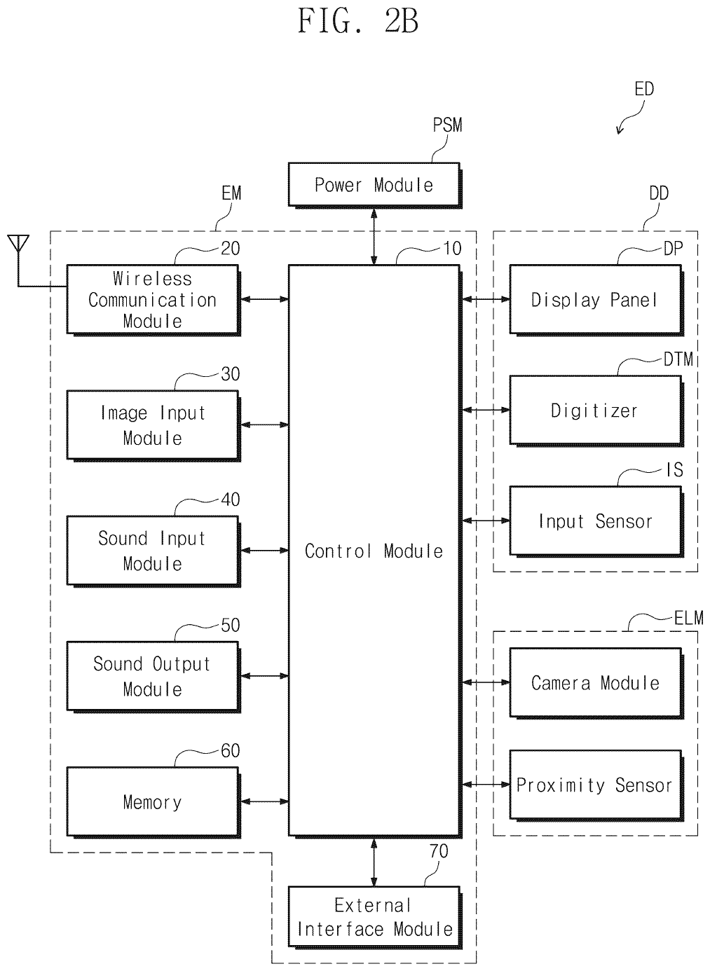

As illustrated in FIG. 1B, a distance between the first non-folding area NFA1 and the second non-folding area NFA2 may be substantially the same as the radius of curvature R1, or, in one or more embodiments, as illustrated in FIG. 1C, the distance between the first non-folding area NFA1 and the second non-folding area NFA2 may be less than the radius of curvature R1. FIGS. 1B-1C each is a view illustrated based on the display surface DS, and housings HM (see FIG. 2A) constituting an outer appearance of the electronic apparatus ED may be in contact with each other in end areas of the first non-folding area NFA1 and the second non-folding area NFA2.

FIG. 2A is an exploded perspective view of an electronic apparatus (or an electronic device) according to one or more embodiments of the present disclosure. FIG. 2B is a block diagram of an electronic apparatus (or an electronic device) according to one or more embodiments of the present disclosure.

As illustrated in FIGS. 2A-2B, an electronic apparatus (or an electronic device) ED may include a window WM, a display device DD, an electronic module EM, an electronic optical module ELM, a power module PSM, and a housing HM. In one or more embodiments, the electronic apparatus ED may further include a mechanical structure to control a folding operation of the display device DD.

The window WM may provide a front surface of the electronic apparatus ED. The window WM may include, for example, a thin-film glass substrate. The window WM may include a bezel pattern that defines the non-display area NDA as described in one or more embodiments. The window WM may further include functional layers, such as a window protection layer, a hard coating layer, a window adhesive layer, an anti-fingerprint layer, and/or the like.

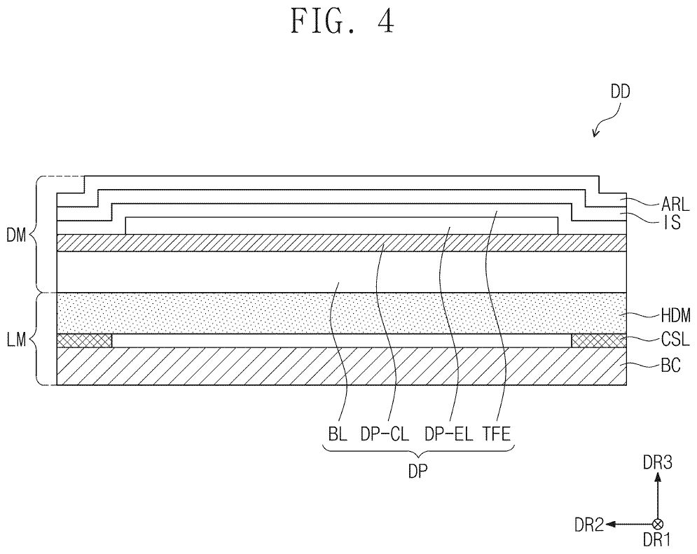

The display device DD may generate an image and detect an external input. The display device DD may include a display module DM (see FIG. 4).

The display device DD may include at least a display panel DP. FIG. 2A illustrates the display panel DP of a layered structure of the display device DD, but the display device DD may substantially further include a plurality of components above and below the display panel DP. The layered structure of the display device DD will be described later in more detail.

The display panel DP is not limited and may be an emissive display panel, for example, an organic light emitting display panel or a quantum dot light emitting display layer. The display panel DP may be a display panel including a subminiature light emitting element, such as a micro LED or a nano LED.

The display panel DP may include a display area DP-DA and a non-display area DP-NDA that correspond to the display area DA (see FIG. 1A) and the non-display area NDA (see FIG. 1A) of the electronic apparatus ED, respectively. In the present disclosure, “an area/portion that corresponds to another area/portion” refers to that the area/portion overlaps the other area/portion and is not limited to the meaning that the areas/portions having substantially the same surface area.

The display panel DP may include a sensing area DP-TA that corresponds to the sensing area TA in FIG. 1A. The sensing area DP-TA may be an area having a lower resolution than the display area DP-DA.

As illustrated in FIG. 2A, a driving chip DIC may be on the non-display area DP-NDA of the display panel DP. A flexible circuit board FCB may be coupled to the non-display area DP-NDA of the display panel DP. The flexible circuit board FCB may be connected to a main circuit board. The main circuit board may be one electronic part that constitutes the electronic module EM.

The driving chip DIC may include driving elements, for example, a data driving circuit, to drive pixels of the display panel DP. FIG. 2A illustrates a structure in which the driving chip DIC is mounted on the display panel DP, but embodiments of the present disclosure are not limited thereto. For example, the driving chip DIC may be mounted on the flexible circuit board FCB.

As illustrated in FIG. 2B, the display device DD may further include an input sensor IS and a digitizer DTM. The input sensor IS may detect a user's input. The input sensor IS that uses a capacitance method may be above the display panel DP. The digitizer DTM may detect an input of a stylus pen. The digitizer DTM that uses an electromagnetic induction method may be below the display panel DP.

The electronic module EM may include a control module 10, a wireless communication module 20, an image input module 30, a sound input module 40, a sound output module 50, a memory 60, an external interface module 70, and/or the like. The electronic module EM may include a main circuit board, and the foregoing modules may be mounted on the main circuit board or electrically connected to the main circuit board through a flexible circuit board. The electronic module EM may be electrically connected to the power module PSM.

Referring to FIG. 2A, the electronic module EM may be in each of a first housing HM1 and a second housing HM2, and the power module PSM may be in each of the first housing HM1 and the second housing HM2. In one or more embodiments, the electronic module EM in the first housing HM1 and the electronic module EM in the second housing HM2 may be electrically connected to each other through a flexible circuit board.

Referring to FIG. 2B, the control module 10 may control the overall operation

of the electronic apparatus ED. For example, the control module 10 may activate or inactivate the display device DD in response to a user's input. The control module 10 may control the image input module 30, the sound input module 40, the sound output module 50, and/or the like, in response to the user's input. The control module 10 may include at least one microprocessor.

The wireless communication module 20 may transmit/receive a wireless signal to/from another terminal using a Bluetooth or WiFi channel. The wireless communication module 20 may transmit/receive an audio signal using a general communication channel. The wireless communication module 20 may include a plurality of antenna modules.

The image input module 30 may process an image signal and convert the image signal to image data displayable on the display device DD. The sound input module 40 may receive an external sound signal through a microphone in a recording mode, an audio recognition mode, and/or the like, and may convert the external audio signal to an electronic audio data. The sound output module 50 may convert sound data received from the wireless communication module 20, or sound data stored in the memory 60, and output the converted sound data.

The external interface module 70 may serve as an interface connected to an external charger, a wired/wireless data port, a card socket (e.g., a memory card and a SIM/UIM card), and/or the like.

The power module PSM may supply power required for the overall operation of the electronic apparatus ED. The power module PSM may include a battery device that is generally available or generally used.

The electronic optical module ELM may be an electronic part that outputs or receives an optical signal. The electronic optical module ELM may include a camera module and/or a proximity sensor. The camera module may photograph an external image through the sensing area DP-TA.

The housing HM illustrated in FIG. 2A may be coupled to the window WM and may accommodate the other modules as described in one or more embodiments. The housing HM is illustrated as including the first housing HM1 and the second housing HM2 separated from each other, but embodiments of the present disclosure are not limited thereto. In one or more embodiments, the electronic apparatus ED may further include a hinge structure to connect the first housing HM1 and the second housing HM2 to each other.

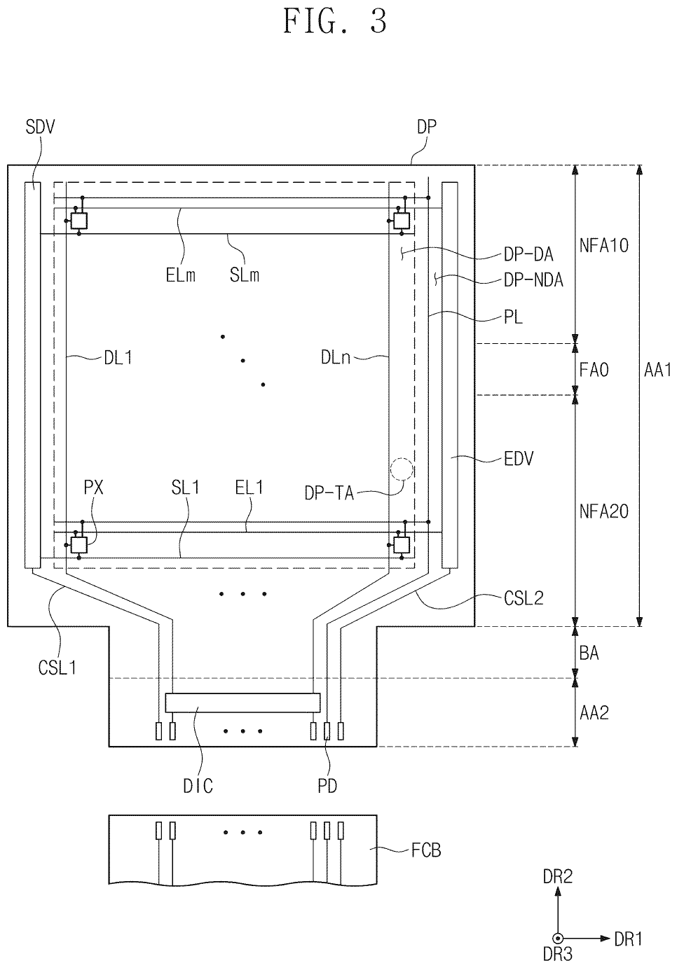

FIG. 3 is a plan view of a display panel according to one or more embodiments of the present disclosure.

Referring to FIG. 3, a display panel DP may include a display area DP-DA and a non-display area DP-NDA around (or surrounding) the display area DP-DA. The display area DP-DA and the non-display area DP-NDA may be divided according to the presence of a pixel PX. The pixel PX may be in the display area DP-DA. A scan driver SDV, a data driver, and a light emitting driver EDV may be in the non-display area DP-NDA. The data driver may be a partial circuit included in a driving chip DIC as illustrated in FIG. 3.

The display panel DP may include a first area AA1, a second area AA2, and a bending area BA that are divided in the second direction DR2. The second area AA2 and the bending area BA may be a partial area of the non-display area DP-NDA. The bending area BA may be between the first area AA1 and the second area AA2.

The first area AA1 may be an area that corresponds to the display surface DS in FIG. 1A. The first area AA1 may include a first non-folding area NFA10, a second non-folding area NFA20, and a folding area FAO. The first non-folding area NFA10, the second non-folding area NFA20, and the folding area FAO may correspond to the second non-folding area NFA2, the first non-folding area NFA1, and the folding area FA, respectively, in FIGS. 1A-1C.

A length of each of the bending area BA and the second area AA2 may be smaller than a length of the first area AA1 in the first direction DR1. An area having a small length in a bending-axis direction may be more easily bent.

The display panel DP may include a plurality of pixels PX, a plurality of scan lines SL1 to SLm, a plurality of data lines DL1 to DLn, a plurality of light emitting lines EL1 to ELm, a first control line CSL1, a second control line CSL2, a power line PL, and a plurality of pads PD. In one or more embodiments, m and n may each be a natural number. The pixels PX may be connected to the scan lines SL1 to SLm, the data lines DL1 to DLn, and the light emitting lines EL1 to ELm.

The scan lines SL1 to SLm may extend in the second direction DR2 to be connected to the scan driver SDV. The data lines DL1 to DLn may extend in the second direction DR2 and be connected to the driving chip DIC via the bending area BA. The light emitting lines EL1 to ELm may extend in the first direction DR1 to be connected to the light emitting driver EDV.

The power line PL may include a portion that extends in the second direction DR2 and a portion that extends in the first direction DR1. The portion that extends in the first direction DR1 and the portion that extends in the second direction DR2 may be on different layers. The portion, which extends in the second direction DR2, of the power line PL may extend to the second area AA2 via the bending area BA. The power line PL may supply a first voltage to the pixels PX.

A first control line CSL1 may be connected to the scan driver SDV and extend toward a lower end of the second area AA2 via the bending area BA. A second control line CSL2 may be connected to the light emitting driver EDV and extend toward the lower end of the second area AA2 via the bending area BA.

The pads PD may be adjacent to the lower end of the second area AA2 on a plane. The driving chip DIC, the power line PL, the first control line CSL1, and the second control line CSL2 may be connected to the pads PD. A flexible circuit board FCB may be electrically connected to the pads PD through an anisotropic conductive (e.g., electrically conductive) adhesive layer.

A sensing area DP-TA may be an area having a higher light transmittance and a lower resolution than the display area DP-DA. The light transmittance and the resolution may be measured in a reference surface area, and the sensing area DP-TA may be an area having a smaller occupation rate of a light blocking structure in the reference surface area than the display area DP-DA. The light blocking structure may include a conductive (e.g., electrically conductive) pattern of a circuit layer, an electrode of a light emitting element, a light blocking pattern, and/or the like. The sensing area DP-TA may be an area on which a smaller number of pixels PX are in the reference surface area (or substantially the same surface area) compared to the display area DP-DA.

FIG. 4 is a cross-sectional view of a display device according to one or more embodiments of the present disclosure.

Referring to FIG. 4, a display device DD may include a display module DM and a lower member LM.

The display module DM may include a display panel DP, an input sensor IS, and an anti-reflection layer ARL. The display panel DP may include a base layer BL, a circuit layer DP-CL, a light emitting element layer DP-EL, and an encapsulating layer TFE.

The base layer BL may provide a base surface on which the circuit layer DP-CL is disposed or provided. The base layer BL may be a flexible substrate capable of being bent, folded, rolled, and/or the like. The base layer BL may be a glass substrate, a metal substrate, a polymer substrate, and/or the like. However, embodiments of the present disclosure are not limited thereto, and the base layer BL may be an inorganic layer, an organic layer, and/or a composite material layer.

The base layer BL may have a multilayer structure. For example, the base layer BL may include a first synthetic resin layer, a multi-layered or single-layered inorganic layer, and a second synthetic resin layer on the multi-layered or single-layered inorganic layer. The first synthetic resin layer and the second synthetic resin layer may each include a polyimide-based resin, but embodiments of the present disclosure are not limited thereto.

The circuit layer DP-CL may be on the base layer BL. The circuit layer DP-CL may include an insulation layer, a semiconductor pattern, a conductive (e.g., electrically conductive) pattern, a signal line, and/or the like.

The light emitting element layer DP-EL may be on the circuit layer DP-CL. The light emitting element layer DP-EL may include a light emitting element. For example, the light emitting element may include an organic light emitting material, an inorganic light emitting material, an organic-inorganic light emitting material, a quantum dot, a quantum rod, a micro LED, and/or a nano LED.

The encapsulating layer TFE may be on the light emitting element layer DP-EL. The encapsulating layer TFE may protect the light emitting element layer DP-EL from moisture, oxygen, and/or foreign matter, such as dust particles. The encapsulating layer TFE may include at least one inorganic layer. The encapsulating layer TFE may include a layered structure of inorganic layer/organic layer/inorganic layer.

The input sensor IS may be directly on the display panel DP. The display panel DP and the input sensor IS may be formed or provided through a substantially continuous process. In one or more embodiment, “being disposed directly on or “being directly on” may refer to that a third component is not between the input sensor IS and the display panel DP. For example, a separate adhesive member may not be between the input sensor IS and the display panel DP.

The anti-reflection layer ARL may be directly on the input sensor IS. The

anti-reflection layer ARL may reduce reflectance (or reduce a degree of occurrence of reflectance) of external light incident from the outside of the display device DD. The anti-reflection layer ARL may include color filters. The color filters may have a set or predetermined arrangement. For example, the color filters may be arranged or provided considering emissive colors of pixels included in the display panel DP. In one or more embodiments, the anti-reflection layer ARL may further include a black matrix adjacent to the color filters.

In one or more embodiments of the present disclosure, positions between the sensor layer IS and the anti-reflection layer ARL may be exchanged. In one or more embodiments of the present disclosure, the anti-reflection layer ARL may be replaced with a polarizing film. The polarizing film may be coupled to the input sensor IS through an adhesive layer.

The lower member LM may include a heat dissipating member HDM and a bottom chassis BC. The lower member LM may further include a foam tape CSL between the heat dissipating member HDM and the bottom chassis BC.

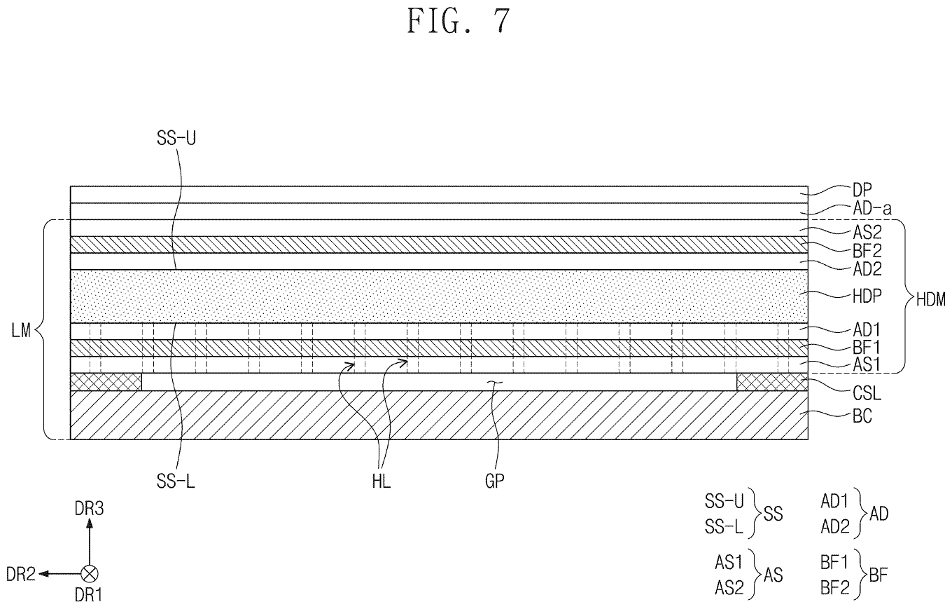

The heat dissipating member HDM may be below the display panel DP. The heat dissipating member HDM may be a member that supports the display panel DP and performs a heat dissipation function to discharge heat generated if (e.g., when) the display panel DP is driven. The heat dissipating member HDM may be below the display panel DP and include a material having an excellent or suitable thermal diffusion property to effectively or suitably dissipate the heat generated from a substantially entire surface if (e.g., when) the display panel DP is driven. One or more components of the heat dissipating member HDM will be described in more detail with reference to FIG. 7 and the following drawings.

The bottom chassis BC may be below the heat dissipating member HDM. The bottom chassis BC may be a component that supports components thereon, for example, the display panel DP and/or the like. The bottom chassis BC may include a material having a set or predetermined rigidity in order to support the components thereon. The bottom chassis BC may include, for example, a single metal material or an alloy of a plurality of metal materials. For example, the bottom chassis BC may be SUS 304. However, the bottom chassis BC is not limited thereto and may include one or more suitable metal materials. In one or more embodiments, the bottom chassis BC may include a polymer film having a high modulus.

In one or more embodiments, an opening portion may be defined in a portion of the bottom chassis BC, and the opening portion may be defined in an area that overlaps the folding area FA (see FIG. 1A) as described in one or more embodiments. A shape of the portion of the bottom chassis BC may be relatively easily changed due to the opening portion.

The foam tape CSL may be between the bottom chassis BC and the heat dissipating member HDM and may attach the bottom chassis BC and the heat dissipating member HDM to each other. The foam tape CSL may be around (or may surround) an edge of each of the bottom chassis BC and the heat dissipating member HDM. The foam tape CSL may include a double-sided tape. Adhesion of one surface of the foam tape CSL may be lower (e.g., less or weaker) than adhesion of the other surface. The foam tape CSL may include a film-type (or kind) tape, such as a thermal foam tape.

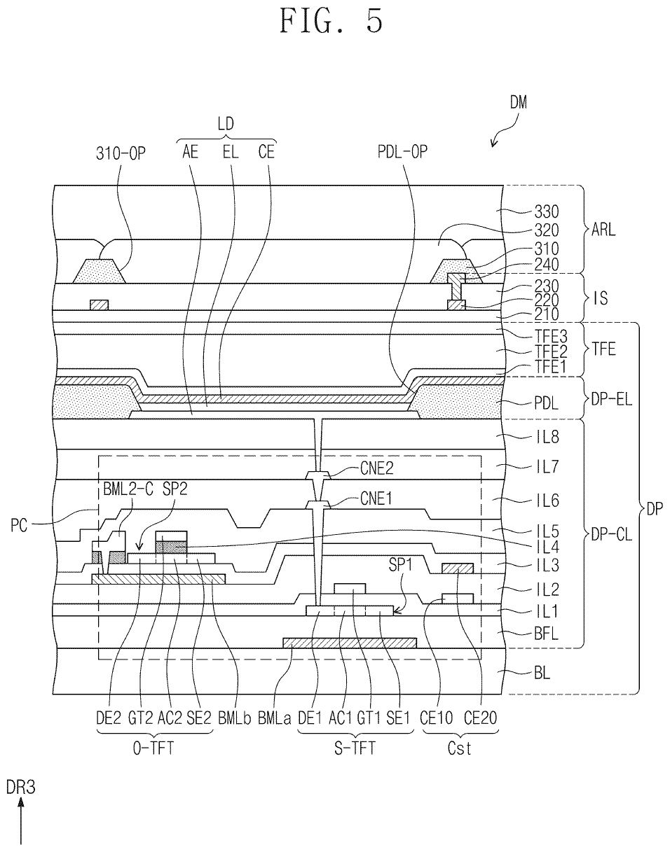

FIG. 5 is a cross-sectional view of a portion of a display module according to one or more embodiments of the present disclosure. A portion of the display module DM according to one or more embodiments illustrated in FIG. 4 is illustrated in more detail in FIG. 5. For example, components that correspond one pixel of the display module DM according to one or more embodiments are illustrated in more detail in FIG. 5.

FIG. 5 illustrates one light emitting element LD and a silicon transistor S-TFT and an oxide transistor O-TFT of a pixel circuit PC. At least one selected from among a plurality of transistors included in the pixel circuit PC may be the oxide transistor O-TFT, and the other transistors may each be the silicon transistor S-TFT.

A buffer layer BFL may be on a base layer BL. The buffer layer BFL may prevent a phenomenon (or reduce a degree or occurrence of a phenomenon) in which metal atoms and/or impurities are spread from the base layer BL to a first semiconductor pattern SP1 above the buffer layer BFL. The first semiconductor pattern SP1 may include an active region AC1 of the silicon transistor S-TFT. The buffer layer BFL may adjust a heat supply rate during a crystallization process to form or provide the first semiconductor pattern SP1 so that the first semiconductor pattern SP1 is substantially uniformly formed or provided.

A first rear metal layer BMLa may be below the silicon transistor S-TFT, and a second rear metal layer BMLb may be below the oxide transistor O-TFT. The first rear metal layer BMLa and the second rear metal layer BMLb may be disposed or provided to overlap the pixel circuit PC. The first rear metal layer BMLa and the second rear metal layer BMLb may block external light from reaching the pixel circuit PC.

The first rear metal layer BMLa may be disposed or provided to correspond to at least a partial area of the pixel circuit PC. The first rear metal layer BMLa may be disposed or provided so as to overlap a driving transistor embodied as the silicon transistor S-TFT.

The first rear metal layer BMLa may be between the base layer BL and the buffer layer BFL. In one or more embodiments of the present disclosure, an inorganic barrier layer may be further between the first rear metal layer BMLa and the buffer layer BFL. The first rear metal layer BMLa may be connected to an electrode or a line and may receive a constant voltage or signal from the electrode and the line. According to one or more embodiments of the present disclosure, the first rear metal layer BMLa may be a floating electrode in the form of being isolated from another electrode or line.

The second rear metal layer BMLb may be disposed or provided to correspond to a lower portion of the oxide transistor O-TFT. The second rear metal layer BMLb may be between a second insulation layer IL2 and a third insulation layer IL3. The second rear metal layer BMLb may be on substantially the same layer as a second electrode CE20 of a storage capacitor Cst. The second rear metal layer BMLb may be connected to a contact electrode BML2-C and receive a constant voltage or signal. The contact electrode BML2-C may be on substantially the same layer as a gate GT2 of the oxide transistor O-TFT.

Each of the first rear metal layer BMLa and the second rear metal layer BMLb may include a reflective metal. For example, each of the first rear metal layer BMLa and the second rear metal layer BMLb may include silver (Ag), silver (Ag)-containing alloy, molybdenum (Mo), molybdenum (Mo)-containing alloy, aluminum (Al), aluminum (Al)-containing alloy, aluminum nitride (AIN), tungsten (W), tungsten nitride (WN), copper (Cu), a p⁺ doped amorphous (e.g., non-crystalline) silicon, and/or the like. The first rear metal layer BMLa and the second rear metal layer BMLb may include substantially the same material, or, in one or more embodiments, may include different materials.

According to one or more embodiments of present disclosure, the second rear metal layer BMLb may not be provided. The first rear metal layer BMLa may extend to below the oxide transistor O-TFT, and the first rear metal layer BMLa may block light incident from below the oxide transistor O-TFT.

The first semiconductor pattern SP1 may be on the buffer layer BFL. The first semiconductor pattern SP1 may include a silicon semiconductor. For example, the silicon semiconductor may include amorphous (e.g., non-crystalline) silicon, polycrystalline silicon, and/or the like. For example, the first semiconductor pattern SP1 may include low-temperature polysilicon.

FIG. 5 illustrates a portion of the first semiconductor pattern SP1 on the buffer layer BFL, and the first semiconductor pattern SP1 may be further on another area. The first semiconductor pattern SP1 may be arranged or provided over pixels according to a set or specific rule. The first semiconductor pattern SP1 may have different electrical properties depending on whether the first semiconductor pattern SP1 is doped or not. The first semiconductor pattern SP1 may include a first region having relatively high conductivity (e.g., electrical conductivity) and a second region having relatively low conductivity (e.g., electrical conductivity). The first region may be doped with a negative type (n-type) dopant or a positive type (p-type) dopant. A p-type transistor may include a doped region doped with the p-type dopant, and an n-type transistor may include a doped region doped with the n-type dopant. The second region may be a non-doped region or may be doped to have a lower concentration than the first region.

The conductivity (e.g., electrical conductivity) of the first region may be higher than the conductivity (e.g., electrical conductivity) of the second region, and the first region may substantially serve as an electrode or a signal line. The second region may substantially correspond to an active region (or channel) of a transistor. In one or more embodiments, one portion of the first semiconductor pattern SP1 may be an active region of the transistor, another portion thereof may be a source or a drain of the transistor, and still another portion thereof may be a connection electrode or a connection signal line.

A source region SE1 (or source), the active region AC1 (or channel), and a drain region DE1 (or drain) of the silicon transistor S-TFT may be formed or provided from the first semiconductor pattern SP1. The source region SE1 and the drain region DE1 may extend from the active region AC1 in opposite (e.g., facing away) directions on a cross-section.

A first insulation layer IL1 may be on the buffer layer BFL. The first insulation layer IL1 may overlap a plurality of pixels in common and cover the first semiconductor pattern SP1. The first insulation layer IL1 may be an inorganic layer and/or an organic layer and have a single-layer or multilayer structure. The first insulation layer IL1 may include at least one of an aluminum oxide, a titanium oxide, a silicon oxide, a silicon nitride, a silicon oxynitride, a zirconium oxide, or a hafnium oxide. In one or more embodiments, the first insulation layer IL1 may be a silicon oxide layer having a single-layer structure. In addition to the first insulation layer IL1, an insulation layer of a circuit layer DP-CL to be described later in more detail may be an inorganic layer and/or an organic layer and may have a single-layer or multilayer structure. The inorganic layer may include at least one selected from among the foregoing materials, but embodiments of the present disclosure are not limited thereto.

A gate GT1 of the silicon transistor S-TFT may be on the first insulation layer IL1. The gate GT1 may be a portion of a metal pattern. The gate GT1 may overlap the active region AC1. The gate GT1 may function as a mask in a process to dope the first semiconductor pattern SP1. The gate GT1 may include titanium (Ti), silver (Ag), silver-containing alloy, molybdenum (Mo), molybdenum-containing alloy, aluminum (Al), aluminum-containing alloy, aluminum nitride (AIN), tungsten (W), tungsten nitride (WN), copper (Cu), indium tin oxide (ITO), indium zinc oxide (IZO), and/or the like, but embodiments of the present disclosure are not limited thereto.

The second insulation layer IL2 may be on the first insulation layer IL1 and may cover the gate GT1. The third insulation layer IL3 may be on the second insulation layer IL2. The second electrode CE20 of the storage capacitor Cst may be between the second insulation layer IL2 and the third insulation layer IL3. A first electrode CE10 of the storage capacitor Cst may be between the first insulation layer IL1 and the second insulation layer IL2.

A second semiconductor pattern SP2 may be on the third insulation layer IL3. The second semiconductor pattern SP2 may include an active region AC2 of the oxide transistor O-TFT to be described later in more detail. The second semiconductor pattern SP2 may include an oxide semiconductor. The second semiconductor pattern SP2 may include a transparent (e.g., substantially transparent) conductive (e.g., electrically conductive) oxide (TCO), such as an indium tin oxide (ITO), an indium zinc oxide (IZO), an indium gallium zinc oxide (IGZO), a zinc oxide (e.g., ZnO), and/or an indium oxide (e.g., In₂O₃).

The oxide semiconductor may include a plurality of regions divided according to whether the transparent (e.g., substantially transparent) conductive (e.g., electrically conductive) oxide is reduced or not. A region in which the transparent (e.g., substantially transparent) conductive (e.g., electrically conductive) oxide is reduced (hereinafter referred to as a reduced region) may have higher conductivity (e.g., electrical conductivity) than a region in which the transparent (e.g., substantially transparent) conductive (e.g., electrically conductive) oxide is not reduced (hereinafter referred to as a non-reduced region). The reduced region may substantially serve as a source/drain or a signal line of a transistor. The non-reduced region may substantially correspond to a semiconductor region (or active region or channel) of the transistor. In one or more embodiments, a partial region of the second semiconductor pattern SP2 may be a semiconductor region of a transistor, another partial region thereof may be a source region/drain region of the transistor, and still another partial region thereof may be a signal transfer region.

A source region SE2 (or source), the active region AC2 (or channel), and a drain region DE2 (or drain) of the oxide transistor O-TFT may be formed or provided from the second semiconductor pattern SP2. The source region SE2 and the drain region DE2 may extend from the active region AC2 in opposite (e.g., facing away) directions on a cross-section.

A fourth insulation layer IL4 may be on the third insulation layer IL3. As illustrated in FIG. 5, the fourth insulation layer IL4 may be an insulation pattern that overlaps the gate GT2 of the oxide transistor O-TFT and exposes each of the source region SE2 and the drain region DE2 of the oxide transistor O-TFT. As illustrated in FIG. 5, the fourth insulation layer IL4 may cover the active region AC2 of the second semiconductor pattern SP2.

As illustrated in FIG. 5, the gate GT2 of the oxide transistor O-TFT may be on the fourth insulation layer IL4. The gate GT2 of the oxide transistor O-TFT may be a portion of a metal pattern. The gate GT2 of the oxide transistor O-TFT may overlap the active region AC2.

A fifth insulation layer IL5 may be on the fourth insulation layer IL4 and may cover the gate GT2. A first connection electrode CNE1 may be on the fifth insulation layer IL5. The first connection electrode CNE1 may be connected to the drain region DE1 of the silicon transistor S-TFT through a contact hole that passes through the first insulation layer IL1, the second insulation layer IL2, the third insulation layer IL3, and the fifth insulation layer IL5.

A sixth insulation layer IL6 may be on the fifth insulation layer IL5. A second connection electrode CNE2 may be on the sixth insulation layer IL6. The second connection electrode CNE2 may be connected to the first connection electrode CNE1 through a contact hole that passes through the sixth insulation layer IL6. A seventh insulation layer IL7 may be on the sixth insulation layer IL6 and may cover the second connection electrode CNE2. An eighth insulation layer IL8 may be on the seventh insulation layer IL7.

Each of the sixth insulation layer IL6, the seventh insulation layer IL7, and the eighth insulation layer IL8 may be an organic layer. For example, each of the sixth insulation layer IL6, the seventh insulation layer IL7, and the eighth insulation layer IL8 may include a general purpose polymer, such as benzocyclobutene (BCB), polyimide, hexamethyldisiloxane (HMDSO), polymethyl methacrylate (PMMA), polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, and/or the like.

The light emitting element LD may include a first electrode AE, a light emitting layer EL, and a second electrode CE. The second electrode CE may be provided on a plurality of light emitting elements in common.

The first electrode AE of the light emitting element LD may be on the eighth insulation layer IL8. The first electrode AE of the light emitting element LD may be a (semi-)transmissive electrode or a reflective electrode. According to one or more embodiments of the present disclosure, the first electrode AE of the light emitting element LD may include a reflective layer made of silver (Ag), magnesium (Mg), aluminum (Al), platinum (Pt), palladium (Pd), gold (Au), nickel (Ni), neodymium (Nd), iridium (Ir), chromium (Cr), a (e.g., any suitable) compound thereof, and/or the like, and a transparent (e.g., substantially transparent) or semi-transparent electrode layer on the reflective layer. The transparent (e.g., substantially transparent) or semi-transparent electrode layer may include at least one selected from the group consisting of an indium tin oxide (ITO), an indium zinc oxide (IZO), an indium gallium zinc oxide (IGZO), a zinc oxide (e.g., ZnO), or an indium oxide (e.g., In₂O₃) and an aluminum-doped zinc oxide (AZO). For example, the first electrode AE of the light emitting element LD may include a layered structure of ITO/Ag/ITO.

A pixel defining film PDL may be on the eighth insulation layer IL8. The pixel defining film PDL may have a light absorbing property, and for example, the pixel defining film PDL may have a substantially black color. The pixel defining film PDL may include a black component (e.g., a black coloring agent). The black component may include a black dye and/or a black pigment. The black component may include a carbon black, a metal, such as chrome, and/or an oxide thereof. The pixel defining film PDL may correspond to a light blocking pattern having a light blocking property.

The pixel defining film PDL may cover a portion of the first electrode AE of the light emitting element LD. For example, an opening PDL-OP that exposes a portion of the first electrode AE of the light emitting element LD may be defined in the pixel defining film PDL. The pixel defining film PDL may increase a distance between the second electrode CE and an edge of the first electrode AE of the light emitting element LD. Thus, the pixel defining film PDL may serve to prevent an arc and/or the like from occurring (or to reduce a degree or occurrence of an arc and/or the like) at the edge of the first electrode AE.

In one or more embodiments, a hole control layer may be between the first electrode AE and the light emitting layer EL. The hole control layer may include a hole transport layer and may further include a hole injection layer. An electron control layer may be between the light emitting layer EL and the second electrode CE. The electron control layer may include an electron transport layer and may further include an electron injection layer. The hole control layer and the electron control layer may be provided, in common, in the plurality of pixels PX (see FIG. 3A) by using an open mask.

An encapsulating layer TFE may be on the light emitting element layer DP-EL. The encapsulating layer TFE may include an inorganic layer TFE1, an organic layer TFE2, and an inorganic layer TFE3 that are stacked in sequence, but the layers constituting the encapsulating layer TFE are not limited thereto.

The inorganic layers TFE1 and TFE3 may protect a light emitting element layer DP-EL from moisture and/or oxygen, and the organic layer TFE2 may protect the light emitting element layer DP-EL from foreign matter, such as dust particles. The inorganic layers TFE1 and TFE3 may include a silicon nitride layer, a silicon oxynitride layer, a silicon oxide layer, a titanium oxide layer, an aluminum oxide layer, and/or the like. The organic layer TFE2 may include an acrylic organic layer, but embodiments of the present disclosure are not limited thereto.

An input sensor IS may be on the display panel DP. The input sensor IS may be referred to as a sensor, an input sensing layer, or an input sensing panel. The input sensor IS may include a sensor base layer 210, a first conductive layer 220, a sensing insulation layer 230, and a second conductive layer 240.

The sensor base layer 210 may be directly on the display panel DP. The sensor base layer 210 may be an inorganic layer including at least one of a silicon nitride, a silicon oxynitride, or a silicon oxide. In one or more embodiments, the sensor base layer 210 may be an organic layer including an epoxy resin, an acrylic resin, and/or an imide-based resin. The sensor base layer 210 may have a single-layer structure or have a multilayer structure in which layers are stacked in the third direction DR3.

Each of the first conductive layer 220 and the second conductive layer 240 may have a single-layer structure or have a multilayer structure in which layers are stacked in the third direction DR3. The first conductive layer 220 and the second conductive layer 240 may include conductive (e.g., electrically conductive) lines that define a mesh-shaped sensing electrode. The conductive (e.g., electrically conductive) lines may not overlap the opening PDL-OP but overlap the pixel defining film P DL.

The conductive (e.g., electrically conductive) layer having a single-layer structure may include a metal layer or a transparent (e.g., substantially transparent) conductive (e.g., electrically conductive) layer. The metal layer may include molybdenum, silver, titanium, copper, aluminum, or an (e.g., any suitable) alloy thereof. The transparent (e.g., substantially transparent) conductive (e.g., electrically conductive) layer may include a transparent (e.g., substantially transparent) conductive (e.g., electrically conductive) oxide, such as an indium tin oxide (ITO), an indium zinc oxide (IZO), a zinc oxide (e.g., ZnO), and/or an indium zinc tin oxide (IZTO). In one or more embodiments, the transparent (e.g., substantially transparent) conductive (e.g., electrically conductive) layer may include a conductive (e.g., electrically conductive) polymer, such as poly (3,4-ethylenedioxythiophene) (PEDOT), metal nanowire, graphene, and/or the like.

The conductive (e.g., electrically conductive) layer having a multilayer structure may include metal layers stacked in sequence. The metal layers may have a three-layer structure of, for example, titanium/aluminum/titanium. The conductive (e.g., electrically conductive) layer having a multilayer structure may include at least one metal layer and at least one transparent (e.g., substantially transparent) conductive (e.g., electrically conductive) layer.

The sensing insulation layer 230 may be between the first conductive layer 220 and the second conductive layer 240. The sensing insulation layer 230 may include an inorganic film. The inorganic film may include at least one of an aluminum oxide, a titanium oxide, a silicon oxide, a silicon nitride, a silicon oxynitride, a zirconium oxide, or a hafnium oxide.

In one or more embodiments, the sensing insulation layer 230 may include an organic film. The organic film may include at least one of acryl-based resin, a methacryl-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

An anti-reflection layer ARL may be on the input sensor IS. The anti-reflection layer ARL may include a division layer 310, a plurality of color filters 320, and a planarization layer 330.

A material constituting the division layer 310 is not limited as long as being a material that absorbs light. The division layer 310 may be a layer having a black color, and in one or more embodiments, the division layer 310 may include a black component (e.g., a black coloring agent). The black component may include a black dye and/or a black pigment. The black component may include a carbon black, a metal, such as chrome, and/or an oxide thereof.

The division layer 310 may cover the second conductive layer 240 of the input sensor IS. The division layer 310 may prevent external light from being reflected (or reduce a degree or occurrence of reflection of external light) by the second conductive layer 240. The division layer 310 may not be provided in a partial area of the display module DM. The area in which the division layer 310 is not provided may have a higher transmittance than the other area.

An opening 310-OP may be defined in the division layer 310. The opening 310-OP may overlap the first electrode AE of the light emitting element LD. One of the plurality of color filters 320 may overlap the first electrode AE of the light emitting element LD. One of the plurality of color filters 320 may cover the opening 310-OP. Each of the plurality of color filters 320 may be in contact with the division layer 310.

The planarization layer 330 may cover the division layer 310 and the plurality of color filters 320. The planarization layer 330 may include an organic matter, and a flat (e.g., substantially flat) surface may be provided on a top surface of the planarization layer 330. In one or more embodiments of the present disclosure, the planarization layer 330 may not be provided.

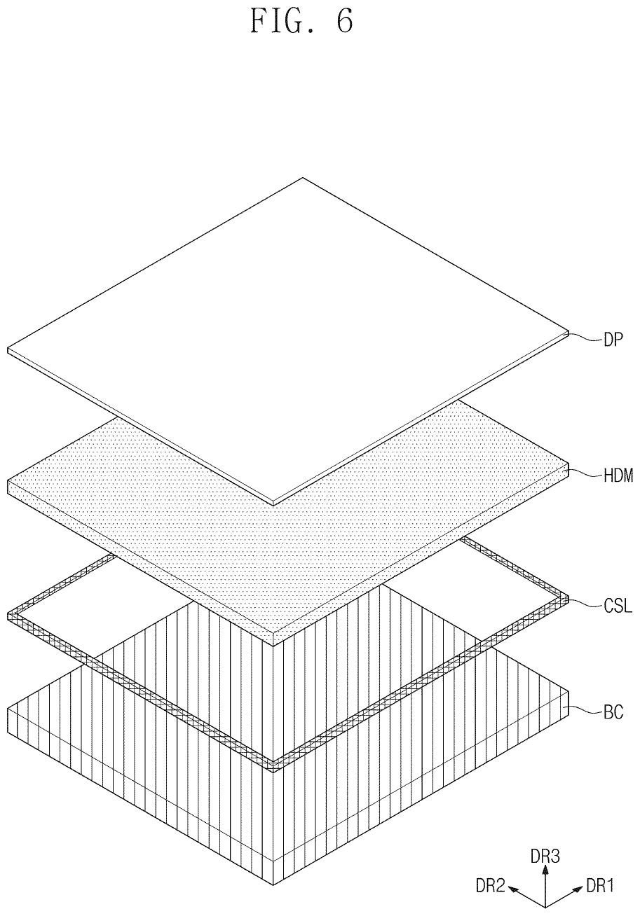

FIG. 6 is an exploded perspective view of one or more components of a display device according to one or more embodiments of the present disclosure. FIG. 7 is a cross-sectional view of one or more components of a display device according to one or more embodiments of the present disclosure. Each of FIGS. 6-7 illustrates a display panel DP and components of a lower member LM below the display panel DP.

Referring to FIGS. 4, 6, and 7, a display device DD may include the display panel DP and the lower member LM below the display panel DP. The display device DD may further include an additional adhesive layer AD-a between the display panel DP and the lower member LM. The additional adhesive layer AD-a may include a pressure-sensitive adhesive. The additional adhesive layer AD-a may include, for example, an acrylic pressure-sensitive adhesive. The additional adhesive layer AD-a may be between the display panel DP and a heat dissipating member HDM.

The lower member LM may include the heat dissipating member HDM and a bottom chassis BC. The lower member LM may further include a foam tape CSL between the heat dissipating member HDM and the bottom chassis BC.

The heat dissipating member HDM may be below the display panel DP. The heat dissipating member HDM may be a member that supports the display panel DP and performs a heat dissipation function to discharge heat generated if (e.g., when) the display panel DP is driven. The heat dissipating member HDM may be below the display panel DP and may include a material having an excellent or suitable thermal diffusion property to effectively or suitably dissipate the heat generated from a substantially entire surface if (e.g., when) the display panel DP is driven.

The heat dissipating member HDM may include a heat dissipating plate HDP, an adhesive layer AD on at least one surface of the heat dissipating plate HDP, and a base material film BF spaced and/or apart (e.g., spaced apart or separated) from the heat dissipating plate HDP with the adhesive layer AD therebetween. As an example, FIG. 7 illustrates one or more embodiments in which the adhesive layer AD and the base material film BF are on each of both surfaces SS (e.g., two opposite surfaces) of the heat dissipating plate HDP. However, embodiments of the present disclosure are not limited thereto, and the adhesive layer AD and the base material film BF may be on only one surface of the heat dissipating plate HDP.

The heat dissipating plate HDP may include a top surface SS-U relatively adjacent to the display panel DP and a bottom surface SS-L relatively adjacent to the bottom chassis BC. The adhesive layer AD may be on at least one of the top surface SS-U or the bottom surface SS-L. The adhesive layer AD may be in contact with at least one of the top surface SS-U or the bottom surface SS-L. The adhesive layer AD may include a first adhesive layer AD1 on the bottom surface SS-L and a second adhesive layer AD2 on the top surface SS-U.

The heat dissipating plate HDP may include graphite. As the heat dissipating plate HDP includes graphite having a high thermal conductivity, the display device DD according to one or more embodiments may effectively or suitably dissipate the heat generated if (e.g., when) the display panel DP is driven.

The heat dissipating plate HDP may have a larger thickness than another component included in the heat dissipating member HDM. This thickness of the heat dissipating plate HDP may be, for example, about 700 micrometers to about 1000 micrometers. The heat dissipating plate HDP may have a thickness of about 800 micrometers to about 850 micrometers. As the heat dissipating plate HDP that substantially performs a heat dissipation function is provided to have a large thickness, the heat dissipating member HDM according to one or more embodiments may effectively or suitably dissipate the heat generated if (e.g., when) the display panel DP is driven.

The base material film BF may be spaced and/or apart (e.g., spaced apart or separated) from the top surface SS-U or the bottom surface SS-L of the heat dissipating plate HDP with the adhesive layer AD therebetween. The base material film BF may be on at least one of a lower side or an upper side of the heat dissipating plate HDP. The base material film BF may include a first base material film BF1, which is spaced and/or apart (e.g., spaced apart or separated) from the bottom surface SS-L of the heat dissipating plate HDP with the first adhesive layer AD1 therebetween, and a second base material film BF2, which is spaced and/or apart (e.g., spaced apart or separated) from the top surface SS-U of the heat dissipating plate HDP with the second adhesive layer AD2 therebetween.

The base material film BF may include a polymer film. The base material film BF may include at least one selected from among polyethylene terephthalate (PET), polyimide (PI), polymethyl methacrylate (PMMA), polycarbonate (PC), polyethylene (PE), and polyacrylate. The base material film BF may include, for example, a polyethylene terephthalate film.

Each of the base material film BF and the adhesive layer AD may have a smaller thickness than the heat dissipating plate HDP. The thickness of each of the base material film BF and the adhesive layer AD may be about 10 micrometers to about 100 micrometers. The thickness of each of the base material film BF and the adhesive layer AD may be about 20 micrometers to about 30 micrometers. In one or more embodiments, the thickness of the base material film BF and the thickness of the adhesive layer AD may be substantially the same as each other. A thickness of the first adhesive layer AD1 and a thickness of the first base material film BF1 may be substantially the same as each other. A thickness of the second adhesive layer AD2 and a thickness of the second base material film BF2 may be substantially the same as each other.

The heat dissipating member HDM may further include an anti-static layer AS on one surface of the base material film BF. For example, the anti-static layer AS may be disposed or provided so as to be spaced and/or apart (e.g., spaced apart or separated) from the adhesive layer AD with the base material film BF therebetween. The anti-static layer AS may be in contact with one surface of the base material film BF. The anti-static layer AS may include a first anti-static layer AS1 on one surface of the first base material film BF1 and a second anti-static layer AS2 on one surface of the second base material film BF2. Although FIG. 7 illustrates a certain embodiment in which the anti-static layer AS is disposed or provided so as to be spaced and/or apart (e.g., spaced apart or separated) from the adhesive layer AS with the base material film BF therebetween, embodiments of the present disclosure are not limited thereto, and the anti-static layer AS may be between the base material film BF and the adhesive layer AS. The anti-static layer AS may be provided by coating one surface of the base material film BF with an anti-static material.

The bottom chassis BC may be below the heat dissipating member HDM. The bottom chassis BC may be below the bottom surface SS-L of the heat dissipating plate HDP of the heat dissipating member HDM. The bottom chassis BC may be below the first base material film BF1 and the first anti-static layer AS1 of the heat dissipating member HDM.

The bottom chassis BC may be a component that supports components thereon, for example, the display panel DP, the heat dissipating member HDM, and/or the like. The bottom chassis BC may include a material having a set or predetermined rigidity in order to support the components thereon. The bottom chassis BC may include, for example, a single metal material or an alloy of a plurality of metal materials. For example, the bottom chassis BC may be SUS 304. However, the bottom chassis BC is not limited thereto and may include one or more suitable metal materials. In one or more embodiments, the bottom chassis BC may include a polymer film having a high modulus.

In one or more embodiments, an opening portion may be defined in a portion of the bottom chassis BC, and the opening portion may be defined in an area that overlaps the folding area FA (see FIG. 1A) as described in one or more embodiments. A shape of the portion of the bottom chassis BC may be relatively easily changed due to the opening portion.

The foam tape CSL may be between the bottom chassis BC and the heat dissipating member HDM and may attach the bottom chassis BC and the heat dissipating member HDM to each other. The foam tape CSL may be between the bottom chassis BC and the first anti-static layer AS1. The foam tape CSL may be around (may surround) an edge of each of the bottom chassis BC and the heat dissipating member HDM. As the foam tape CSL is around (or surrounds) the edge of each of the bottom chassis BC and the heat dissipating member HDM, a gap GP may be defined in a central portion between the heat dissipating member HDM and the bottom chassis BC. The gap GP may be filled with air. The foam tape CSL may include a film-type (or kind) tape, such as a thermal foam tape.

In the heat dissipating member HDM, at least one hole HL may be in the components below the heat dissipating plate HDP. The hole HL may be in plurality. In one or more embodiments, the hole HL may be provided so as to pass through at least the first adhesive layer AD1 on the bottom surface SS-L of the heat dissipating plate HDP. The hole HL may be provided so as to pass through all of the first adhesive layer AD1, the first base material film BF1, and the first anti-static layer AS1 that are in sequence on the bottom surface SS-L of the heat dissipating plate HDP. The at least one hole HL that passes through the components below the heat dissipating plate HDP may be provided to adjust pressures inside and outside the display device DD.

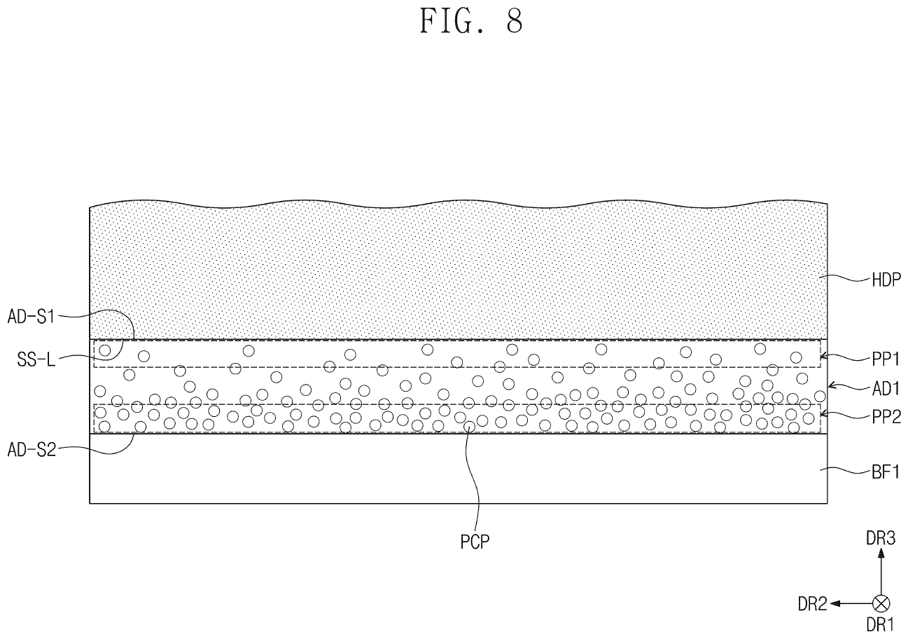

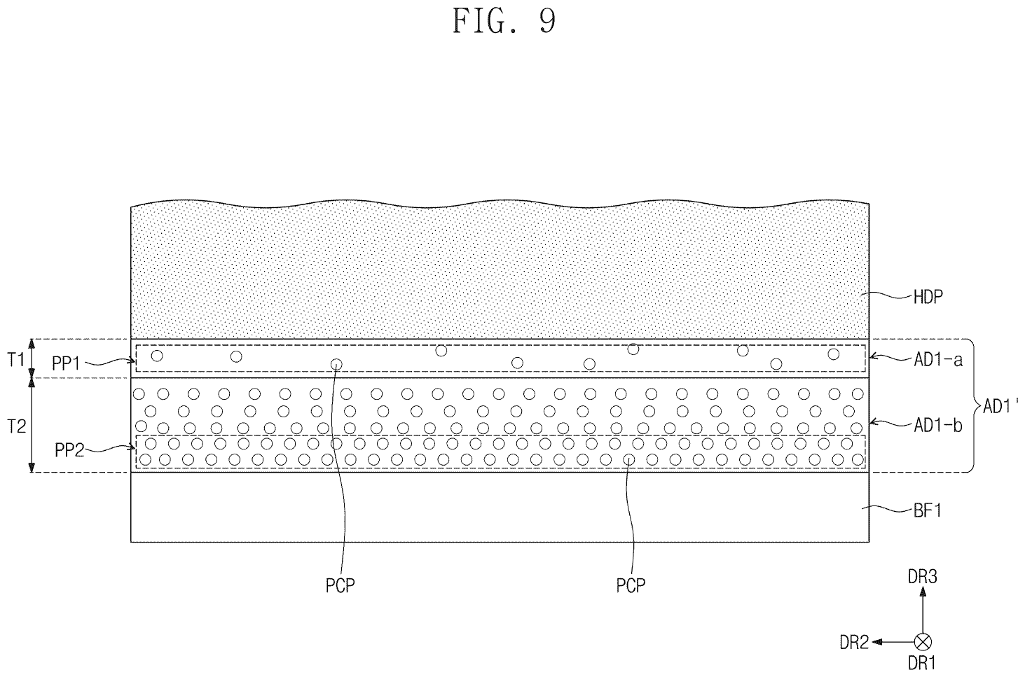

FIGS. 8-9 each is an enlarged cross-sectional view of one or more components of a heat dissipating member according to one or more embodiments of the present disclosure. Each of FIGS. 8-9 illustrates an enlarged cross-sectional view of a portion of a heat dissipating plate HDP of the heat dissipating member HDM as illustrated in FIG. 7, and a first adhesive layer AD1 or AD1′ and a first base material film BF1, each of which may be below the heat dissipating plate HDP.

Referring to FIGS. 7-8 together, the first adhesive layer AD1 may be on a bottom surface SS-L of the heat dissipating plate HDP, and the first base material film BF1 may be below the first adhesive layer AD1. A first surface AD-S1 of the first adhesive layer AD1 may be in contact with the bottom surface SS-L of the heat dissipating plate HDP, and a second surface AD-S2 of the first adhesive layer AD1 may be in contact with one surface of the first base material film BF1. The second surface AD-S2 of the first adhesive layer AD1 may be in contact with a top surface of the first base material film BF1.

The first adhesive layer AD1 may include a polyurethane. The first adhesive layer AD1 may include a hot-melt adhesive including the polyurethane. The first adhesive layer AD1 may include the polyurethane that is a thermoplastic polymer and may include a polyol constituting a polyurethane chain, and polyisocyanate. The first adhesive layer AD1 may be derived from an adhesive composition including a polyol that includes a polycarbonate polyol and a polyisocyanate that crosslinks with the polyol. The polyol and the polyisocyanate which are included in the first adhesive layer AD1 may be urethane-bonded.

The first adhesive layer AD1 may include a polyol that includes a polycarbonate polyol (PCP). The first adhesive layer AD1 may include the polycarbonate polyol (PCP) as one polyol component that is a constituent component of the polyurethane. The first adhesive layer AD1 may include the polycarbonate polyol (PCP) and may further include another additional polyol. For example, the first adhesive layer AD1 may include the polycarbonate polyol (PCP), and, in one or more embodiments, may further include a polyester polyol, a polytetramethylene ether glycol (PTMG or PTMEG), a diethylene glycol, a dipropylene glycol, a polyethylene glycol, and/or the like. The first adhesive layer AD1 may include at least one of a toluene diisocyanate (TDI) or a methylene diphenyl isocyanate (MDI) as the polyisocyanate that is a constituent component of the polyurethane.

In the first adhesive layer AD1, if (e.g., when) a total content (e.g., amount) of the polyol and the polyisocyanate is taken to be 100 parts by weight, the polycarbonate polyol (PCP) may have a content (e.g., amount) of about 20 parts by weight to about 40 parts by weight. If (e.g., when) the content (e.g., amount) of the polycarbonate polyol (PCP) is less than about 20 parts by weight based on the total content (e.g., amount) of 100 parts by weight of the polyol and the polyisocyanate, a portion of the polyurethane of the first adhesive layer AD1 may be hydrolyzed under conditions of high temperature and high humidity to cause a defect in which the portion is visible as a white blur from the outside. If (e.g., when) the content (e.g., amount) of the polycarbonate polyol (PCP) is more than about 40 parts by weight based on the total content (e.g., amount) of 100 parts by weight of the polyol and the polyisocyanate, adhesion of the first adhesive layer AD1 may be reduced to cause a defect in which the heat dissipating plate HDP and the first base material film BF1 are separated from the first adhesive layer AD1.

The first adhesive layer AD1 may include a first portion PP1 adjacent to the heat dissipating plate HDP and a second portion PP2 adjacent to the first base material film BF1. In the first adhesive layer AD1, the first portion PP1, the second portion PP2, and a portion therebetween may not be components divided by a separate interface, but portions having a virtual boundary based on adjacent components. For example, in the first adhesive layer AD1, the first portion PP1, the second portion PP2, and the portion therebetween may have a shape of one body.

In the first adhesive layer AD1, the polycarbonate polyol (PCP) may be included so as to have a content (e.g., amount) that is different between the portions divided based on a thickness direction. In the first adhesive layer AD1, the content (e.g., amount) of the polycarbonate polyol (PCP) may be different between the first portion PP1 adjacent to the heat dissipating plate HDP and the second portion PP2 adjacent to the first base material film BF1. The content (e.g., amount) of the polycarbonate polyol (PCP) in the first portion PP1 may be less than the content (e.g., amount) of the polycarbonate polyol (PCP) in the second portion PP2. In one or more embodiments, the content (e.g., amount) of the polycarbonate polyol (PCP) of the first portion PP1 may be about 20 parts by weight to about 25 parts by weight based on the total content (e.g., amount) of 100 parts by weight of the polyol and the polyisocyanate. The content (e.g., amount) of the polycarbonate polyol (PCP) of the second portion PP2 may be about 35 parts by weight to about 40 parts by weight based on the total content (e.g., amount) of 100 parts by weight of the polyol and the polyisocyanate.

In the first adhesive layer AD1, the content (e.g., amount) of the polycarbonate polyol (PCP) may be gradually changed in the third direction DR3 that is the thickness direction. In the first adhesive layer AD1, the content (e.g., amount) of the polycarbonate polyol (PCP) may gradually increase from the first portion PP1 adjacent to the heat dissipating plate HDP to the second portion PP2 adjacent to the first base material film BF1.

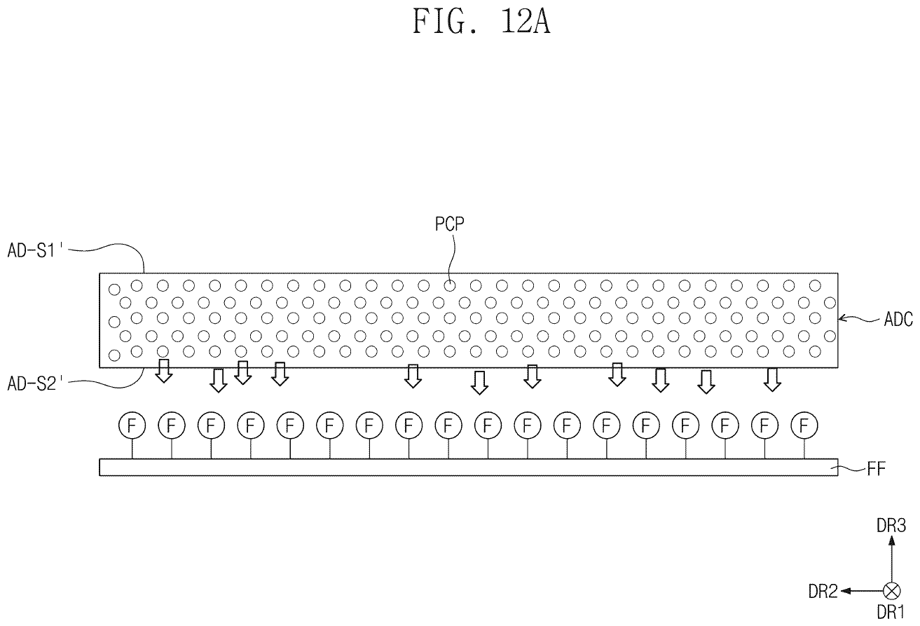

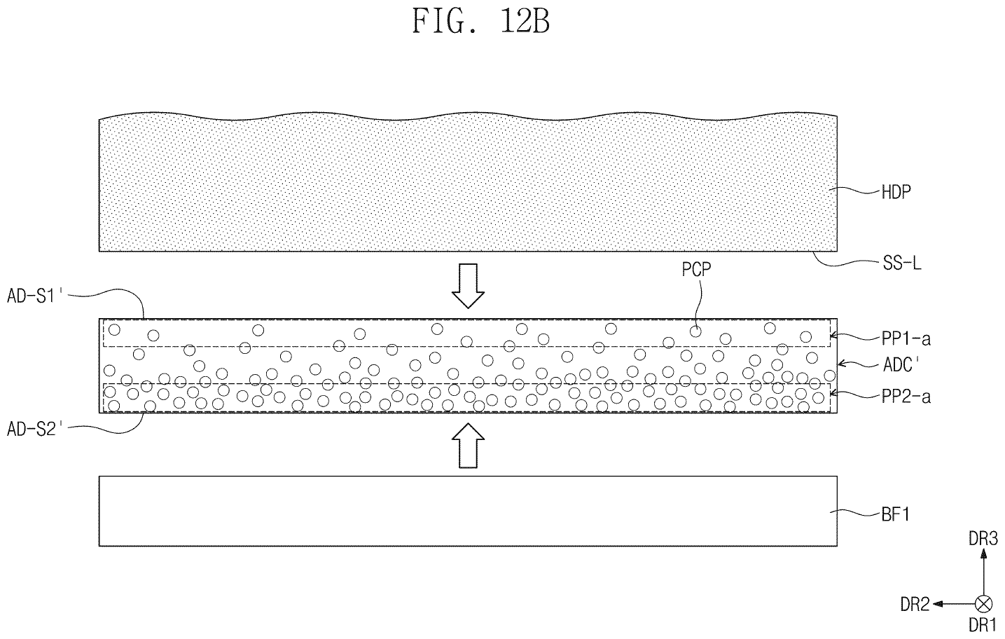

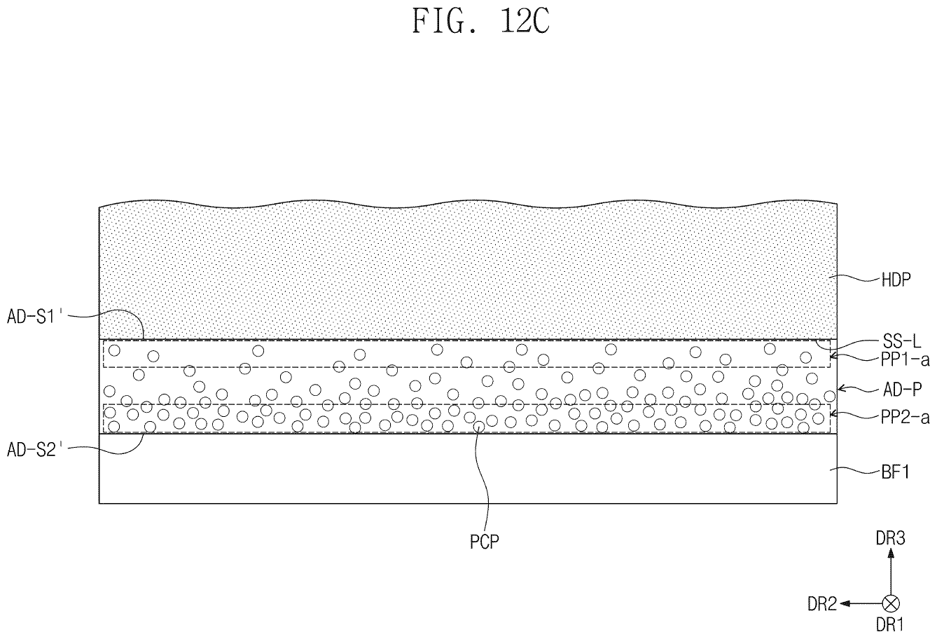

The first adhesive layer AD1 may further include a perfluoropolyether. The perfluoropolyether may be covalently bonded to the polycarbonate polyol (PCP) to provide a fluorine substituent to the polycarbonate polyol (PCP) in the first adhesive layer AD1. As the perfluoropolyether is provided, the content (e.g., amount) of the polycarbonate polyol (PCP) in the first adhesive layer AD1 may be adjusted so as to be changed through a functional film FF (see FIG. 12A) including a fluorine in a process to form or provide the first adhesive layer AD1.

Referring to FIGS. 7 and 9 together, the first adhesive layer AD1′ may have a double-layer structure unlike certain embodiment as illustrated in FIG. 8. The first adhesive layer AD1′ may include a first sub-adhesive layer AD1-a below the heat dissipating plate HDP and a second sub-adhesive layer AD1-b below the first sub-adhesive layer AD1-a. An interface may be provided between the first sub-adhesive layer AD1-a and the second sub-adhesive layer AD1-b so that the layers are divided.

The first adhesive layer AD1′ may include a first portion PP1 adjacent to the heat dissipating plate HDP and a second portion PP2 adjacent to the first base material film BF1. The first portion PP1 may be provided to the first sub-adhesive layer AD1-a, and the second portion PP2 may be provided to the second sub-adhesive layer AD1-b.

In the first adhesive layer AD1′, the polycarbonate polyol (PCP) may be included so as to have a content (e.g., amount) that is different between the portions divided based on a thickness direction. In the first adhesive layer AD1′, the polycarbonate polyol (PCP) may be included so as to have a content (e.g., amount) that is different between the sub-adhesive layers AD1-a and AD1-b divided based on the thickness direction. In the first adhesive layer AD1′, the content (e.g., amount) of the polycarbonate polyol (PCP) may be different between the first sub-adhesive layer AD1-a adjacent to the heat dissipating plate HDP and the second sub-adhesive layer AD1-b adjacent to the first base material film BF1. The content (e.g., amount) of the polycarbonate polyol (PCP) in the first sub-adhesive layer AD1-a may be less than the content (e.g., amount) of the polycarbonate polyol (PCP) in the second sub-adhesive layer AD1-b. In one or more embodiments, the content (e.g., amount) of the polycarbonate polyol (PCP) of the first sub-adhesive layer AD1-a may be about 20 parts by weight to about 25 parts by weight based on the total content of 100 parts by weight of the polyol and the polyisocyanate. The content (e.g., amount) of the polycarbonate polyol (PCP) of the second sub-adhesive layer AD1-b may be about 35 parts by weight to about 40 parts by weight based on the total content (e.g., amount) of 100 parts by weight of the polyol and the polyisocyanate. In each of the first sub-adhesive layer AD1-a and the second sub-adhesive layer AD1-b, the polycarbonate polyol (PCP) may be included to have a substantially uniform content (e.g., amount) throughout the layer.

The first sub-adhesive layer AD1-a and the second sub-adhesive layer AD1-b may have different thicknesses. The first sub-adhesive layer AD1-a may have a smaller thickness than the second sub-adhesive layer AD1-b. A thickness T1 of the first sub-adhesive layer AD1-a may be, for example, about 1 micrometer to about 10 micrometers. A thickness T2 of the second sub-adhesive layer AD1-b may be, for example, about 15 micrometers to about 25 micrometers.

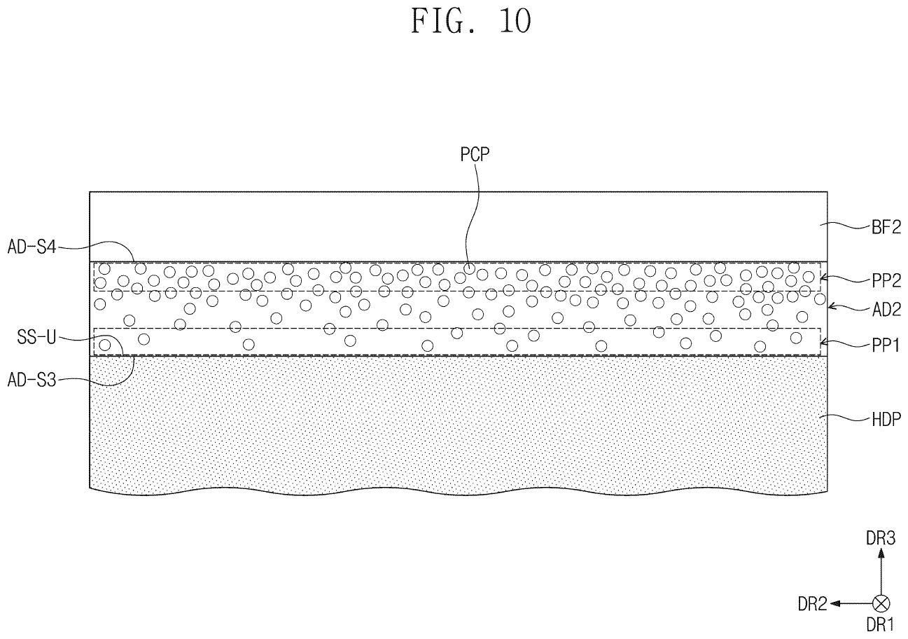

FIG. 10 is an enlarged cross-sectional view of one or more components of a heat dissipating member according to one or more embodiments of the present disclosure. FIG. 10 illustrates an enlarged cross-sectional view of a portion of a heat dissipating plate HDP of the heat dissipating member HDM illustrated in FIG. 7, and a second adhesive layer AD2 and a second base material film BF2, each of which may be above the heat dissipating plate HDP.

Referring to FIGS. 7 and 10 together, the second adhesive layer AD2 may be on a top surface SS-U of the heat dissipating plate HDP, and the second base material film BF2 may be above the second adhesive layer AD2. A third surface AD-S3 of the second adhesive layer AD2 may be in contact with the top surface SS-U of the heat dissipating plate HDP, and a fourth surface AD-S4 of the second adhesive layer AD2 may be in contact with one surface of the second base material film BF2. The fourth surface AD-S4 of the second adhesive layer AD2 may be in contact with a bottom surface of the second base material film BF2.

The second adhesive layer AD2 may include a polyurethane. The second adhesive layer AD2 may include a hot-melt adhesive including the polyurethane. The second adhesive layer AD2 may include the polyurethane that is a thermoplastic polymer and may include a polyol constituting a polyurethane chain, and polyisocyanate. The second adhesive layer AD2 may be derived from an adhesive composition including a polyol that includes a polycarbonate polyol and a polyisocyanate that crosslinks with the polyol. The polyol and the polyisocyanate which are included in the second adhesive layer AD2 may be urethane-bonded.

The second adhesive layer AD2 may include a polyol that includes a polycarbonate polyol (PCP). The second adhesive layer AD2 may include the polycarbonate polyol (PCP) as one polyol component that is a constituent component of the polyurethane. The second adhesive layer AD2 may include the polycarbonate polyol (PCP) and may further include another additional polyol. For example, the second adhesive layer AD2 may include the polycarbonate polyol (PCP), and, in one or more embodiments, may further include a polyester polyol, a polytetramethylene ether glycol (PTMG or PTMEG), a diethylene glycol, a dipropylene glycol, a polyethylene glycol, and/or the like. The second adhesive layer AD2 may include at least one of a toluene diisocyanate (TDI) or a methylene diphenyl isocyanate (MDI) as the polyisocyanate that is a constituent component of the polyurethane.

In the second adhesive layer AD2, if (e.g., when) a total content (e.g., amount) of the polyol and the polyisocyanate is taken to be 100 parts by weight, the polycarbonate polyol (PCP) may have a content (e.g., amount) of about 20 parts by weight to about 40 parts by weight. If (e.g., when) the content (e.g., amount) of the polycarbonate polyol (PCP) is less than about 20 parts by weight based on the total content (e.g., amount) of 100 parts by weight of the polyol and the polyisocyanate, a portion of the polyurethane of the second adhesive layer AD2 may be hydrolyzed under conditions of high temperature and high humidity to cause a defect in which the portion is visible as a white blur from the outside. If (e.g., when) the content (e.g., amount) of the polycarbonate polyol (PCP) is more than about 40 parts by weight based on the total content (e.g., amount) of 100 parts by weight of the polyol and the polyisocyanate, adhesion of the second adhesive layer AD2 may be reduced to cause a defect in which the heat dissipating plate HDP and the second base material film BF2 are separated from the second adhesive layer AD2.

The second adhesive layer AD2 may include a first portion PP1 adjacent to the heat dissipating plate HDP and a second portion PP2 adjacent to the second base material film BF2. In the second adhesive layer AD2, the first portion PP1, the second portion PP2, and a portion therebetween may not be components divided by a separate interface, but portions having a virtual boundary based on adjacent components. For example, in the second adhesive layer AD2, the first portion PP1, the second portion PP2, and the portion therebetween may have a shape of one body. However, embodiments of the present disclosure are not limited thereto, and the second adhesive layer AD2 may have a double-layer structure in which two layers are separated from each other like the first adhesive layer AD1′ as described in one or more embodiments with reference to FIG. 9.

In the second adhesive layer AD2, the polycarbonate polyol (PCP) may be included so as to have a content (e.g., amount) that is different between the portions divided based on a thickness direction. In the second adhesive layer AD2, the content (e.g., amount) of the polycarbonate polyol (PCP) may be different between the first portion PP1 adjacent to the heat dissipating plate HDP and the second portion PP2 adjacent to the second base material film BF2. The content (e.g., amount) of the polycarbonate polyol (PCP) in the first portion PP1 may be less than the content (e.g., amount) of the polycarbonate polyol (PCP) in the second portion PP2. In one or more embodiments, the content (e.g., amount) of the polycarbonate polyol (PCP) of the first portion PP1 may be about 20 parts by weight to about 25 parts by weight based on the total content (e.g., amount) of 100 parts by weight of the polyol and the polyisocyanate. The content (e.g., amount) of the polycarbonate polyol (PCP) of the second portion PP2 may be about 35 parts by weight to about 40 parts by weight based on the total content (e.g., amount) of 100 parts by weight of the polyol and the polyisocyanate.

In the second adhesive layer AD2, the content (e.g., amount) of the polycarbonate polyol (PCP) may be gradually changed in the third direction DR3 that is the thickness direction. In the second adhesive layer AD2, the content (e.g., amount) of the polycarbonate polyol (PCP) may gradually increase from the first portion PP1 adjacent to the heat dissipating plate HDP to the second portion PP2 adjacent to the second base material film BF2.

The second adhesive layer AD2 may further include a perfluoropolyether. The perfluoropolyether may be covalently bonded to the polycarbonate polyol (PCP) to provide a fluorine substituent to the polycarbonate polyol (PCP) in the second adhesive layer AD2. As the perfluoropolyether is provided, the content (e.g., amount) of the polycarbonate polyol (PCP) in the second adhesive layer AD2 may be adjusted so as to be changed through the functional film FF (see FIG. 12A) including a fluorine in a process to form or provide the second adhesive layer AD2.

In the heat dissipating member HDM in the display device DD according to one or more embodiments of the present disclosure, the adhesive layer AD, which attaches the heat dissipating plate HDP and the base material film BF to each other, may include the polyurethane and may include, as one component, the polycarbonate polyol (PCP) among polyols constituting the polyurethane chain. In the heat dissipating member HDM according to one or more embodiments, the adhesive layer AD, which attaches the heat dissipating plate HDP and the base material film BF to each other, may include the polycarbonate polyol (PCP), and thus a portion of the polyurethane of the adhesive layer AD may be prevented from being hydrolyzed under conditions of a high temperature of about 60° C. or more and under high humidity conditions of a relative humidity of about 90% or more. For example, if (e.g., when) a total content (e.g., amount) of the polyol and the polyisocyanate is taken to be 100 parts by weight, the adhesive layer AD according to one or more embodiments may include the polycarbonate polyol (PCP) in a content (e.g., amount) range of about 20 parts by weight to about 40 parts by weight. In one or more embodiments, an adhesive property of the adhesive layer AD may be maintained, and also the defect in which the portion of the polyurethane of the adhesive layer AD is hydrolyzed may be prevented or reduced, thereby preventing the defect (or reducing a degree or occurrence of the defect) in which the portion is visible as a white blur from the outside.

In the adhesive layer AD in the display device according to one or more embodiments, the content (e.g., amount) of the polycarbonate polyol (PCP) may be different between the first portion PP1 adjacent to the heat dissipating plate HDP and the second portion PP2 adjacent to the base material film BF based on the thickness direction. In the adhesive layer AD according to one or more embodiments, the content (e.g., amount) of the polycarbonate polyol (PCP) in the first portion PP1 may be less than the content (e.g., amount) of the polycarbonate polyol (PCP) in the second portion PP2. In one or more embodiments, a portion, adjacent to the heat dissipating plate HDP, of the adhesive layer AD may have the lower polycarbonate polyol (PCP) content (e.g., amount) and thus may have high adhesion to the heat dissipating plate HDP including graphite, and a portion, adjacent to the base material film BF, of the adhesive layer AD may have the higher polycarbonate polyol (PCP) content (e.g., amount) and thus may prevent one or more components of the adhesive layer AD from being hydrolyzed under conditions of high temperature and high humidity applied from the outside. In one or more embodiments, reliability and display characteristics of the display device DD including the adhesive layer AD may be improved or enhanced.

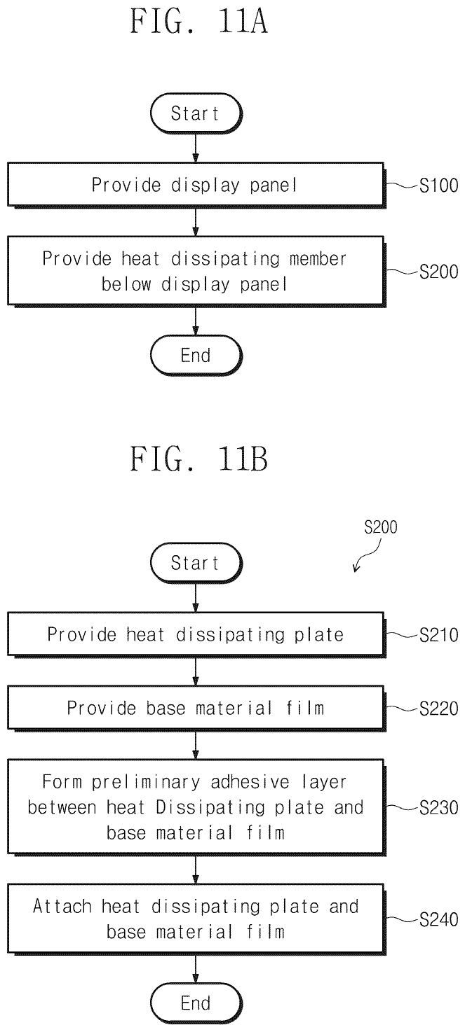

FIG. 11A is a flowchart of a method for manufacturing a display device according to one or more embodiments of the present disclosure. FIG. 11B is a flowchart of one or more acts of a method for manufacturing a display device according to one or more embodiments of the present disclosure. FIG. 11B is a flowchart of acts included in forming or providing a heat dissipating member in order to provide the heat dissipating member below a display panel in the method for manufacturing the display device according to one or more embodiments.

Referring to FIG. 11A, the method for manufacturing the display device according to one or more embodiments may include providing the display panel (S100) and forming or providing the heat dissipating member below the display panel (S200). Referring to FIG. 11B, the forming or providing of the heat dissipating member (S200) may include providing a heat dissipating plate including graphite (S210), providing a base material film (S220), providing an adhesive composition between the heat dissipating plate and the base material film to form or provide a preliminary adhesive layer (S230), and curing the preliminary adhesive layer to attach the heat dissipating plate and the base material film to each other (S240). The heat dissipating member HDM (see FIG. 7) formed or provided according to the forming or providing of the heat dissipating member (S200) may be attached to a lower side of the display panel (see FIG. 7) through the additional adhesive layer AD-a (see FIG. 7).

FIGS. 12A-12C each is a cross-sectional view of one or more acts of a method for manufacturing a display device according to one or more embodiments. FIG. 12A-12C each illustrates, in sequence, a cross-sectional view of providing a heat dissipating plate (S210), providing a base material film (S220), and providing an adhesive composition between the heat dissipating plate and the base material film to form or provide a preliminary adhesive layer (S230) in forming or providing a heat dissipating member (S200).

Referring to FIGS. 12A and 12B, an adhesive composition ADC may include a precursor material to constitute a polyurethane. The adhesive composition ADC may include a polyol constituting a polyurethane chain, and polyisocyanate in order to form or provide the polyurethane that is a thermoplastic polymer. The adhesive composition ADC may include the polyol and the polyisocyanate that crosslinks with the polyol. The polyol and the polyisocyanate which are included in the adhesive composition ADC may then be urethane-bonded in a curing process.

The adhesive composition ADC may include a polyol that includes a polycarbonate polyol (PCP). The adhesive composition ADC may include the polycarbonate polyol (PCP) as one component of the foregoing polyol. The adhesive composition ADC may include the polycarbonate polyol (PCP) and may further include another additional polyol. For example, the adhesive composition ADC may include the polycarbonate polyol (PCP), and, in one or more embodiments, may further include a polyester polyol, a polytetramethylene ether glycol (PTMG or PTMEG), a diethylene glycol, a dipropylene glycol, a polyethylene glycol, and/or the like. The adhesive composition ADC may include at least one of a toluene diisocyanate (TDI) or a methylene diphenyl isocyanate (MDI) as the polyisocyanate that is a constituent component of the polyurethane.

In the adhesive composition ADC, if (e.g., when) a total content (e.g., amount) of the polyol and the polyisocyanate is taken to be 100 parts by weight, the polycarbonate polyol (PCP) may have a content (e.g., amount) of about 20 parts by weight to about 40 parts by weight. If (e.g., when) the content (e.g., amount) of the polycarbonate polyol (PCP) is less than about 20 parts by weight based on the total content (e.g., amount) of 100 parts by weight of the polyol and the polyisocyanate, a portion of the polyurethane of the first adhesive layer AD1 (see FIG. 12C) formed or provided through the adhesive composition ADC may be hydrolyzed under conditions of high temperature and high humidity to cause a defect in which the portion is visible as a white blur from the outside. If (e.g., when) the content (e.g., amount) of the polycarbonate polyol (PCP) is more than about 40 parts by weight based on the total content (e.g., amount) of 100 parts by weight of the polyol and the polyisocyanate, adhesion of the first adhesive layer AD1 (see FIG. 12C) formed or provided through the adhesive composition ADC may be reduced to cause a defect in which the heat dissipating plate HDP and the first base material film BF1 are separated from the first adhesive layer AD1 (see FIG. 12C).

The adhesive composition ADC may further include a perfluoropolyether. The perfluoropolyether may be covalently bonded to the polycarbonate polyol (PCP) to provide a fluorine substituent to the polycarbonate polyol (PCP) in the adhesive composition ADC. As the perfluoropolyether is provided, the content (e.g., amount) of the polycarbonate polyol (PCP) in the adhesive composition ADC may be adjusted so as to be changed through a functional film FF including a fluorine in a process to provide the adhesive composition ADC to form or provide the preliminary adhesive layer.

The method for manufacturing the display device according to one or more embodiments may further include providing the functional film FF including the fluorine on one side of the adhesive composition ADC before the forming or providing of the preliminary adhesive layer. As the functional film FF including the fluorine is provided on the one side of the adhesive composition ADC, the polycarbonate polyol (PCP) may flow to the one side or the other side opposing the one side through a force of attraction between molecules and/or the like. In one or more embodiments, the content (e.g., amount) of the polycarbonate polyol (PCP) in the adhesive composition ADC may be changed. For example, as illustrated in FIG. 12A, the adhesive composition ADC may include a top surface AD-S1′ and a bottom surface AD-S2′ opposing thereto, and the functional film FF may be provided so as to be adjacent to the bottom surface AD-S2′. In one or more embodiments, a portion of the polycarbonate polyol (PCP) in the adhesive composition ADC may flow to a lower side of the adhesive composition ADC so that the content (e.g., amount) of the polycarbonate polyol (PCP) in the adhesive composition ADC is changed.

After the providing of the functional film FF, an adhesive composition ADC′ may include a first preliminary portion PP1-a and a second preliminary portion PP2-a which are different in polycarbonate polyol (PCP) content (e.g., amount). The content (e.g., amount) of the polycarbonate polyol (PCP) in the first preliminary portion PP1-a may be less than the content (e.g., amount) of the polycarbonate polyol (PCP) in the second preliminary portion PP2-a. In the adhesive composition ADC′, the content (e.g., amount) of the polycarbonate polyol (PCP) may be gradually changed in the third direction DR3 that is a thickness direction. In the adhesive composition ADC′, the content (e.g., amount) of the polycarbonate polyol (PCP) may gradually increase from the first preliminary portion PP1-a to the second preliminary portion PP2-a. In one or more embodiments, the content (e.g., amount) of the polycarbonate polyol (PCP) of the first preliminary portion PP1-a may be about 20 parts by weight to about 25 parts by weight based on a total content of 100 parts by weight of a polyol and a polyisocyanate. The content (e.g., amount) of the polycarbonate polyol (PCP) of the second preliminary portion PP2-a may be about 35 parts by weight to about 40 parts by weight based on the total content (e.g., amount) of 100 parts by weight of the polyol and the polyisocyanate. In the adhesive composition ADC′, the first preliminary portion PP1-a, the second preliminary portion PP2-a, and a portion therebetween may not be components divided by a separate interface, but portions having a virtual boundary based on adjacent components. For example, in the adhesive composition ADC′, the first preliminary portion PP1-a, the second preliminary portion PP2-a, and the portion therebetween may have a shape of one body.

Referring to FIGS. 12B-12C, after the content (e.g., amount) of the polycarbonate polyol (PCP) of the adhesive composition ADC′ is adjusted, a heat dissipating plate HDP and a first base material film BF1 may be provided, and the adhesive composition ADC′ may be disposed or provided so as to be between the heat dissipating plate HDP and the first base material film BF1, thereby forming or providing a preliminary adhesive layer AD-P. The preliminary adhesive layer AD-P may be provided between the heat dissipating plate HDP and the first base material film BF1, a top surface AD-S1′ of the preliminary adhesive layer AD-P may be in contact with a bottom surface SS-L of the heat dissipating plate HDP, and a bottom surface AD-S2′ of the preliminary adhesive layer AD-P may be in contact with a top surface of the first base material film BF1. In a state in which the preliminary adhesive layer AD-P is between the heat dissipating plate HDP and the first base material film BF1, the content (e.g., amount) of the polycarbonate polyol (PCP) in the first preliminary portion PP1-a adjacent to the heat dissipating plate HDP may be less than the content (e.g., amount) of the polycarbonate polyol (PCP) in the second preliminary portion PP2-a adjacent to the first base material film BF1. After the preliminary adhesive layer AD-P is provided, the preliminary adhesive layer AD-P may be cured to form or provide the first adhesive layer AD1 (see FIG. 8). In one or more embodiments, the preliminary adhesive layer AD-P may include a hot-melt adhesive including a polyurethane and may be naturally cured under room temperature conditions to form or provide the first adhesive layer AD1 (see FIG. 8).

In the display device and the method for manufacturing the display device according to one or more embodiments of the present disclosure, the heat dissipating plate including the graphite may be provided in the display device, thereby improving or enhancing the heat dissipation properties and also preventing or reducing the occurrence of the defects in which the one or more components of the adhesive layer provided on the one surface of the heat dissipating plate are hydrolyzed under the high temperature and high humidity conditions. In one or more embodiments, the reliability and the display characteristics of the display device may be improved or enhanced.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

Although one or more embodiments of the present disclosure have been described with reference to the accompanying drawings, it should be understood that the present disclosure should not be limited to these embodiments but one or more suitable changes and modifications can be made by one ordinary skilled in the art within the spirit and scope of the appended claims and equivalents thereof, the detailed description of the present disclosure, and the accompanying drawings.

Therefore, the present disclosure is not limited to the embodiments as described, but the scope of the present disclosure should be determined by the appended claims and equivalents thereof.

What is claimed is:

1. A display device, comprising:
a display panel;
a heat dissipating member below the display panel; and
a bottom chassis below the heat dissipating member,
wherein the heat dissipating member comprises:
a heat dissipating plate comprising graphite;
an adhesive layer on at least one surface of the heat dissipating plate,
wherein the adhesive layer comprises a polyurethane; and
a base material film spaced apart from the heat dissipating plate with the adhesive layer therebetween,
wherein the adhesive layer comprises a polyol comprising a polycarbonate polyol,
wherein the adhesive layer comprises a first portion adjacent to the heat dissipating plate and a second portion adjacent to the base material film,
wherein, in the adhesive layer, a content of the polycarbonate polyol of the first portion is less than a content of the polycarbonate polyol of the second portion.

2. The display device as claimed in claim 1, wherein, in the adhesive layer, a content of the polycarbonate polyol gradually increases from the heat dissipating plate to the base material film.

3. The display device as claimed in claim 1, wherein the adhesive layer comprises:
a first sub-adhesive layer on one surface of the at least one surface of the heat dissipating plate; and
a second sub-adhesive layer between the first sub-adhesive layer and the base material film,
wherein a content of the polycarbonate polyol of the first sub-adhesive layer is less than a content of the polycarbonate polyol of the second sub-adhesive layer.

4. The display device as claimed in claim 3, wherein a thickness of the second sub-adhesive layer is greater than a thickness of the first sub-adhesive layer.

5. The display device as claimed in claim 1, wherein the adhesive layer further comprises:
a polyisocyanate that crosslinks with the polyol,
wherein, when a total content of the polyol and the polyisocyanate is taken to be 100 parts by weight, a content of the polycarbonate polyol is about 20 parts by weight to about 40 parts by weight.

6. The display device as claimed in claim 5, wherein, in the first portion, when the total content of the polyol and the polyisocyanate is taken to be 100 parts by weight, the content of the polycarbonate polyol is about 20 parts by weight to about 25 parts by weight,
wherein, in the second portion, when the total content of the polyol and the polyisocyanate is taken to be 100 parts by weight, the content of the polycarbonate polyol is about 35 parts by weight to about 40 parts by weight.

7. The display device as claimed in claim 1, wherein a first surface of the adhesive layer is in contact with one surface of the at least one surface of the heat dissipating plate, and
a second surface of the adhesive layer, which opposes the first surface, is in contact with one surface of the base material film.

8. The display device as claimed in claim 1, wherein the heat dissipating member further comprises an anti-static layer spaced apart from the adhesive layer with the base material film therebetween.

9. The display device as claimed in claim 1, wherein the heat dissipating plate comprises:
a bottom surface adjacent to the bottom chassis; and
a top surface adjacent to the display panel,
wherein the adhesive layer comprises:
a first adhesive layer on the bottom surface; and
a second adhesive layer on the top surface, and
wherein at least one hole that passes through the first adhesive layer in a thickness direction is provided in the first adhesive layer.

10. The display device as claimed in claim 1, further comprising a foam tape between the base material film and the bottom chassis.

11. The display device as claimed in claim 1, wherein the heat dissipating plate has a thickness of about 700 micrometers to about 1000 micrometers, and
each of the adhesive layer and the base material film has a thickness of about 10 micrometers to about 100 micrometers.

12. The display device as claimed in claim 1, wherein the display panel comprises:
a first non-folding area;
a second non-folding area; and
a folding area between the first non-folding area and the second non-folding area.

13. The display device as claimed in claim 1, wherein the adhesive layer further comprises a perfluoropolyether,
wherein the perfluoropolyether is covalently bonded to the polycarbonate polyol.

14. The display device as claimed in claim 1, further comprising an additional adhesive layer between the heat dissipating member and the display panel.

15. An electronic device, comprising:
a display panel; and
a heat dissipating member below the display panel,
wherein the heat dissipating member comprises:
a heat dissipating plate comprising graphite;
an adhesive layer on at least one of a bottom surface or a top surface of the heat dissipating plate; and
a base material film spaced apart from the heat dissipating plate with the adhesive layer therebetween,
wherein the adhesive layer comprises a polyol comprising a polycarbonate polyol and a polyisocyanate that crosslinks with the polyol,
wherein, when a total content of the polyol and the polyisocyanate is taken to be 100 parts by weight, a content of the polycarbonate polyol is about 20 parts by weight to about 40 parts by weight,
wherein the adhesive layer comprises a first portion adjacent to the heat dissipating plate and a second portion adjacent to the base material film,
wherein, in the adhesive layer, a content of the polycarbonate polyol of the first portion is less than a content of the polycarbonate polyol of the second portion.

16. The electronic device as claimed in claim 15, wherein the adhesive layer comprises:
a first adhesive layer on the bottom surface; and
a second adhesive layer on the top surface,
wherein the first adhesive layer comprises a first portion adjacent to the heat dissipating plate and a second portion adjacent to the base material film,
wherein, in the first adhesive layer, a content of the polycarbonate polyol of the first portion is less than a content of the polycarbonate polyol of the second portion.

17. The electronic device as claimed in claim 15, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

18. A method for manufacturing a display device, the method comprising:
providing a display panel; and
forming a heat dissipating member below the display panel,
wherein the forming of the heat dissipating member comprises:
providing a heat dissipating plate comprising graphite;
providing a base material film;
providing an adhesive composition between the heat dissipating plate and the base material film to form a preliminary adhesive layer; and
curing the preliminary adhesive layer to attach the heat dissipating plate and the base material film to each other,
wherein the preliminary adhesive layer comprises a polyol comprising a polycarbonate polyol,
wherein the preliminary adhesive layer comprises a first preliminary portion adjacent to the heat dissipating plate and a second preliminary portion adjacent to the base material film,
wherein, in the preliminary adhesive layer, a content of the polycarbonate polyol of the first preliminary portion is less than a content of the polycarbonate polyol of the second preliminary portion.

19. The method as claimed in claim 18, wherein the preliminary adhesive layer further comprises:
a polyisocyanate that crosslinks with the polyol,
wherein, when a total content of the polyol and the polyisocyanate is taken to be 100 parts by weight, a content of the polycarbonate polyol is about 20 parts by weight to about 40 parts by weight.

20. The method as claimed in claim 18, wherein the adhesive composition further comprises a perfluoropolyether, and
wherein the method further comprises providing a functional film comprising a fluorine on one side of the adhesive composition before the forming of the preliminary adhesive layer.
